(19) United States
(12) Patent Application Publication
(10) Pub. No.: US 2018/0187291 A1
(43) Pub. Date: Jul. 5, 2018

(54) Sputtering Target Material

(71) Applicant: Sanyo Special Steel Co., Ltd., Himeji-shi (JP)

(72) Inventors: Hiroyuki Hasegawa, Himeji-shi (JP); Noriaki Matsubara, Himeji-shi (JP)

(21) Appl. No.: 15/740,474

(22) PCT Filed: Jun. 29, 2016
(86) PCT No.: PCT/JP2016/069261

§ 371 Date: Dec. 28, 2017

(30) Foreign Application Priority Data
Jun. 29, 2015 (JP) 2015-129474
Feb. 19, 2016 (JP) 2016-029731

(51) Int. Cl. C22C 1/04; C23C 14/34; B22F 3/14; C22C 23/02; C22C 23/04; C22C 30/00

(52) U.S. Cl. CPC C22C 1/0408; C23C 14/3414; B22F 3/14; B22F 2998/00; C22C 23/04; C22C 30/00; B22F 2301/058; C22C 23/02

(57) ABSTRACT

An object of the present invention is to provide a sintered alloy having high mechanical strength (specifically, high toughness suitable for a sputtering target material) and a sputtering target material including the sintered alloy, and the present invention provides a sintered alloy that includes: Mn; an A-group element consisting of one or more of Ga, Zn, Sn, Ge, Al, and Co; and optionally a B-group element consisting of one or more of Fe, Ni, Cu, Ti, V, Cr, Si, Y, Zr, Nb, Mo, Ru, Rh, Pd, Ag, In, Ta, W, Re, Ir, Pt, Au, Bi, La, Ce, Nd, Sm, Gd, Tb, Dy, and Ho, wherein the balance is an inevitable impurity, wherein the sintered alloy includes one or more of a 1st to a 6th Mn phases that satisfy predetermined conditions.

### CROSS-REFERENCE TO RELATED APPLICATIONS

This application claims the benefit of Japanese Patent Application No. 2015-129474 filed on Jun. 29, 2015 and Japanese Patent Application No. 2016-29731 filed on Feb. 19, 2016, the entire contents of which are incorporated herein by reference.

### BACKGROUND OF THE INVENTION

### Field of the Invention

The present invention relates to a sintered alloy and a sputtering target material comprising the sintered alloy.

### Background Art

Sputtering method is known as one of deposition methods in which high-quality film such as metal film can be formed. In a sputtering method, a sputtering target material is used in forming a film. A sputtering method is a method in which a film is formed on a substrate such as a wafer placed to face a target by giving an impulse on a sputtering target material by charged particles and ejecting particles from the sputtering target material by the impulse force. Since a film is formed in such a manner, considerable load is applied to a sputtering target material during sputtering. Especially, in case of a composition including a great amount of Mn, the sputtering target material may crack during sputtering, which is one of factors to disturb a normal operation of an apparatus.

On the other hand, a sputtering target material as disclosed in, for example, JP-A-2009-74127 (Patent document 1) is known as a sputtering target material including Mn. The Patent document 1 discloses that a sputtering target material is produced by sintering a pure Mn or an alloy powder including Mn using powder metallurgy process including Mn.

### CITATION LIST

### Patent Literature

[PTL 1] Japanese Patent Application Laid-Open Publication No. 2009-74127

### SUMMARY OF THE INVENTION

### Technical Problem

However, conventional sputtering target materials as disclosed in Patent Document 1 have low mechanical strengths such as toughness and are therefore likely to be unable to sufficiently prevent cracking of sputtering target materials that may occur during sputtering.

Thus an object of the present invention is to provide a sintered alloy having high mechanical strength (specifically, high toughness suitable for a sputtering target material) and a sputtering target material comprising the sintered alloy.

### Solution to Problem

The present inventors earnestly examined the aforementioned problems and found that introduction of a Mn phase having a specific composition into a sintered alloy can impart high mechanical strengths (specifically, high toughness suitable for a sputtering target material) to the sintered alloy and thus can prevent a sputtering target material from cracking which may occur during sputtering, and came to complete the present invention.

That is to say, the present invention encompasses the following inventions.

[1] A sintered alloy, comprising:

Mn;

an A-group element consisting of one or more of Ga, Zn, Sn, Ge, Al, and Co; and

optionally a B-group element consisting of one or more of Fe, Ni, Cu, Ti, V, Cr, Si, Y, Zr, Nb, Mo, Ru, Rh, Pd, Ag, In, Ta, W, Re, Ir, Pt, Au, Bi, La, Ce, Nd, Sm, Gd, Tb, Dy, and Ho,

wherein the balance is an inevitable impurity,

wherein the sintered alloy comprises one or more Mn phases selected from the group consisting of:

a 1st Mn phase comprising Mn and Ga in an atomic ratio of Mn:Ga=98:2 to 73:27, wherein the total content of the A-group element other than Ga and the B-group element is 20 at % or less;

a 2nd Mn phase comprising Mn and Zn in an atomic ratio of Mn:Zn=98:2 to 64:36, wherein the total content of the A-group element other than Zn and the B-group element is 20 at % or less;

a 3rd Mn phase comprising Mn and Sn in an atomic ratio of Mn:Sn=98.5:1.5 to 74:26, wherein the total content of the A-group element other than Sn and the B-group element is 20 at % or less;

a 4th Mn phase comprising Mn and Ge in an atomic ratio of Mn:Ge=98.5:1.5 to 79:21, wherein the total content of the A-group element other than Ge and the B-group element is 20 at % or less;

a 5th Mn phase comprising Mn and Al in an atomic ratio of Mn:Al=98:2 to 49:51, wherein the total content of the A-group element other than Al and the B-group element is 20 at % or less; and

a 6th Mn phase comprising Mn and Co in an atomic ratio of Mn:Co=96:4 to 51:49, wherein the total content of the A-group element other than Co and the B-group element is 20 at % or less.

[2] The sintered alloy according to [1], comprising:

10 to 98.5 at % of Mn,

totally 1.5 to 75 at % of the A-group element,

totally 0 to 62 at % of the B-group element,

wherein the balance is an inevitable impurity.

[3] The sintered alloy according to [1] or [2], wherein the total area percentage of the 1st to 6th Mn phases is 10% or more.
[4] The sintered alloy according to any one of [1] to [3], wherein a density of the 1st to 6th Mn phases having sizes of 2 μm or more is one or more per 30000 μm².
[5] The sintered alloy according to any one of [1] to [4], wherein a density of the 1st to 6th Mn phases having sizes of 2 μm or more is one or more per 3000 μm².
[6] The sintered alloy according to any one of [1] to [5], wherein a relative density thereof is 90% or more.
[7] The sintered alloy according to any one of [1] to [6], wherein a flexural strength thereof is 100 MPa or more.
[8] A sputtering target material, comprising the sintered alloy according to any one of [1] to [7].

### Effects of the Invention

According to the present invention, a sintered alloy having high mechanical strength (specifically, high toughness suitable for a sputtering target material) and a sputtering target material comprising the sintered alloy are provided. According to the sintered alloy and the sputtering target material, cracking of the sputtering target material which cracking may occur during deposition by sputtering can be prevented.

### DETAILED DESCRIPTION OF THE INVENTION

The present invention will be described in detail below. The sintered alloy according to the present invention comprises Mn. Mn is an essential component for imparting to the sintered alloy high mechanical strengths (specifically, high toughness suitable for a sputtering target material). The content of Mn is preferably 10 to 98.5 at %, more preferably 15 to 95 at %, still more preferably 18 to 90 at %, based on the total number of atoms included in the sintered alloy. From a viewpoint of sufficiently exerting the effect of Mn, the content of Mn is preferably not less than 10 at %, more preferably not less than 15 at %, still more preferably not less than 18 at %. From a viewpoint of securing the content of the A-group element that is able to sufficiently exert the effect of the A-group element, the content of Mn is preferably not more than 98.5 at %, more preferably not more than 95 at %, still more preferably not more than 90 at %.

The sintered alloy according to the present invention comprises the A-group element consisting of one or more of Ga, Zn, Sn, Ge, Al, and Co. The A-group element is an essential component for imparting to the sintered alloy high mechanical strengths (specifically, high toughness suitable for a sputtering target material). The content of the A-group element is preferably 1.5 to 75 at %, more preferably 2 to 70 at %, still more preferably 5 to 65 at %, based on the total number of atoms included in the sintered alloy. Note that, when the A-group element consists of two or more types of elements, the content of the A-group element refers to the total content of the two or more types of the elements. From a viewpoint of sufficiently exerting the effect of the A-group element, the content of the A-group element is preferably not less than 1.5 at %, more preferably not less than 2 at %, still more preferably not less than 5 at %. When the content of the A-group element exceeds 75 at %, the effect of the A-group element is saturated and the effect corresponding to increase of the content cannot be obtained, and therefore the content of the A-group element is preferably not more than 75 at %, more preferably not more than 70 at %, still more preferably not more than 65 at %.

The sintered alloy according to the present invention may optionally comprise the B-group element consisting of one or more of Fe, Ni, Cu, Ti, V, Cr, Si, Y, Zr, Nb, Mo, Ru, Rh, Pd, Ag, In, Ta, W, Re, Ir, Pt, Au, Bi, La, Ce, Nd, Sm, Gd, Tb, Dy, and Ho. The B-group element can be optionally added in addition to Mn and the A-group element in order to enhance the mechanical strength (specifically toughness) of the sintered alloy. The content of the B-group element is preferably 0 to 62 at %, more preferably 0 to 50 at %, still more preferably 0 to 45 at %, based on the total number of atoms included in the sintered alloy. Note that, when the B-group element consists of two or more types of elements, the content of the B-group element means the total content of the two or more types of the elements. When the content of the B-group element exceeds 62 at %, the effect of the B-group element is saturated and the effect corresponding to increase of the content cannot be obtained, and therefore the content of the B-group element is preferably not more than 62 at %, more preferably not more than 50 at %, still more preferably not more than 45 at %. When the sintered alloy according to the present invention comprises the B-group element, from a viewpoint of sufficiently exerting the effect of the B-group element, the content of the B-group element is preferably not less than 2 at %, more preferably not less than 3 at %, still more preferably not less than 6 at %.

The sintered alloy according to the present invention comprises one or more Mn phases selected from a 1st to a 6th Mn phases. High mechanical strengths (specifically, high toughness suitable for a sputtering target material) can be imparted to the sintered alloy by the 1st to the 6th Mn phases.

The 1st Mn phase satisfies the following conditions.

[Condition A1-1] The 1st Mn phase includes Mn and Ga in an atomic ratio of Mn:Ga=98:2 to 73:27.

[Condition A1-2] The total content of the A-group element other than Ga and the B-group element in the 1st Mn phase is 20 at % or less. In other words, the total content of Mn and Ga in the 1st Mn phase is 80 at % or more. Note that “at %” in the condition A1-2 is calculated on the basis of the total number of atoms included in the 1st Mn phase.

Whether a composition of the 1st Mn phase (a type and content of an element) falls within a predetermined range or not can be confirmed using an energy dispersive X-ray fluorescence spectrometer.

The 1st Mn phase satisfies the conditions A1-1 and A1-2 so that the 1st Mn phase becomes γMn phase or βMn phase that has high toughness, and therefore high mechanical strengths (specifically, high toughness suitable for a sputtering target material) can be imparted to the sintered alloy by the 1st Mn phase. When the atomic ratio of Mn and Ga in the 1st Mn phase falls out of the range that Mn:Ga=98:2 to 73:27 (in other words, Mn/Ga>98/2 or Mn/Ga<73/27), or the total content of the A-group element other than Ga and the B-group element in the 1st Mn phase exceeds 20 at %, toughness of the 1st Mn phase is lowered and the 1st Mn phase becomes fragile phase.

The atomic ratio of Mn and Ga in the 1st Mn phase can be appropriately adjusted within the range that Mn:Ga=98:2 to 73:27, and is preferably Mn:Ga=92:8 to 80:20, more preferably Mn:Ga=90:10 to 82:18.

The total content of the A-group element other than Ga and the B-group element in the 1st Mn phase can be appropriately adjusted within a range of 20 at % or less, and is preferably 18 at % or less, more preferably 15 at % or less. The lower limit of the total content of the A-group element other than Ga and the B-group element in the 1st Mn phase is 0.

The condition A1-2 does not mean that the 1st Mn phase has to include the A-group element other than Ga. In other words, the A-group element included in the 1st Mn phase may consist of only Ga or may consist of Ga and an element other than Ga (one or more types of Zn, Sn, Ge, Al, and Co). When the A-group element included in the 1st Mn phase consists of only Ga, the total content of the A-group element other than Ga included in the 1st Mn phase is 0. When the A-group element included in the 1st Mn phase consists of Ga and an element other than Ga, the total content of the A-group element other than Ga included in the 1st Mn phase is preferably more than 0 and not more than 15 at %, more preferably more than 0 and not more than 10 at %. Note that a type(s) of an element(s) composing the A-group element included in the 1st Mn phase may be a part of a type(s) of an element(s) composing the A-group element included in the sintered alloy according to the present invention or may be all of the type(s) of the element(s). For example, the A-group element included in the 1st Mn phase consists of only Ga when the A-group element included in the sintered alloy according to the present invention consists of only Ga, while the A-group element included in the 1st Mn phase may consist of only Ga or may consist of Ga and one type of element other than Ga when the A-group element included in the sintered alloy according to the present invention consists of Ga and one type of element other than Ga. Additionally, when the A-group element included in the sintered alloy according to the present invention consists of Ga and two types of elements other than Ga, the A-group element included in the 1st Mn phase may consist of only Ga, may consist of Ga and one type of element other than Ga or may consist of Ga and two types of elements other than Ga. Furthermore, when the A-group element included in the sintered alloy according to the present invention consists of Ga and three types of elements other than Ga, the A-group element included in the 1st Mn phase may consist of only Ga, may consist of Ga and one type of element other than Ga, may consist of Ga and two types of elements other than Ga or may consist of Ga and three types of elements other than Ga.

When the A-group element included in the 1st Mn phase consists of Ga and an element other than Ga (one or more types of elements selected from Zn, Sn, Ge, Al, and Co), it is preferable that the 1st Mn phase include the A-group element other than Ga in an atomic ratio that satisfies one or more conditions of Mn:Zn=98:2 to 64:36, Mn:Sn=98.5:1.5 to 74:26, Mn:Ge=98.5:1.5 to 79:21, Mn:Al=98:2 to 49:51, and Mn:Co=96:4 to 51:49. A preferable range of the atomic ratio of Mn and the A-group element other than Ga in the 1st Mn phase is the same as a preferable range described in regard to the 2nd to 6th Mn phases. However, the 1st Mn phase may include the A-group element other than Ga in an atomic ratio that does not satisfy the above-mentioned atomic ratio in addition to the A-group element other than Ga in an atomic ratio that satisfies the above-mentioned atomic ratio.

The condition A1-2 does not mean that the 1st Mn phase has to include the B-group element. In other words, the 1st Mn phase may or may not include the B-group element. When the 1st Mn phase includes the B-group element, the total content of the B-group element included in the 1st Mn phase is preferably more than 0 and not more than 15 at %, more preferably more than 0 and not more than 10 at %. Note that the 1st Mn phase does not include the B-group element when the sintered alloy according to the present invention does not include the B-group element, while the 1st Mn phase may or may not include the B-group element when the sintered alloy according to the present invention includes the B-group element. Additionally, a type(s) of an element(s) composing the B-group element included in the 1st Mn phase may be a part of a type(s) of an element(s) composing the B-group element included in the sintered alloy according to the present invention or may be all of the type(s) of the element(s). For example, when the B-group element included in the sintered alloy according to the present invention consists of two types of elements, the B-group element included in the 1st Mn phase may consist of one type of element or may consist of two types of elements. Furthermore, when the B-group element included in the sintered alloy according to the present invention consists of three types of elements, the B-group element included in the 1st Mn phase may consist of one type of element, may consist of two types of elements or may consist of three types of elements.

The 2nd Mn phase satisfies the following conditions.

[Condition A2-1] The 2nd Mn phase includes Mn and Zn in an atomic ratio of Mn:Zn=98:2 to 64:36.

[Condition A2-2] The total content of the A-group element other than Zn and the B-group element in the 2nd Mn phase is 20 at % or less. In other words, the total content of Mn and Zn in the 2nd Mn phase is 80 at % or more. Note that “at %” in the condition A2-2 is calculated on the basis of the total number of atoms included in the 2nd Mn phase.

Whether a composition of the 2nd Mn phase (a type and content of an element) falls within a predetermined range or not can be confirmed using an energy dispersive X-ray fluorescence spectrometer.

The 2nd Mn phase satisfies the conditions A2-1 and A2-2 so that the 2nd Mn phase becomes γMn phase or βMn phase that has high toughness, and therefore high mechanical strengths (specifically, high toughness suitable for a sputtering target material) can be imparted to the sintered alloy by the 2nd Mn phase. When the atomic ratio of Mn and Zn in the 2nd Mn phase falls out of the range that Mn:Zn=98:2 to 64:36 (in other words, Mn/Zn>98/2 or Mn/Zn<64/36), or the total content of the A-group element other than Zn and the B-group element in the 2nd Mn phase exceeds 20 at %, toughness of the 2nd Mn phase is lowered and the 2nd Mn phase becomes fragile phase.

The atomic ratio of Mn and Zn in the 2nd Mn phase can be appropriately adjusted within the range that Mn:Zn=98:2 to 64:36, and is preferably Mn:Zn=98:2 to 65:35, more preferably Mn:Zn=80:20 to 67:33, still more preferably Mn:Zn=75:25 to 70:30.

The total content of the A-group element other than Zn and the B-group element in the 2nd Mn phase can be appropriately adjusted within a range of 20 at % or less, and is preferably 18 at % or less, more preferably 15 at % or less. Note that the lower limit of the total content of the A-group element other than Zn and the B-group element in the 2nd Mn phase is 0.

The condition A2-2 does not mean that the 2nd Mn phase has to include the A-group element other than Zn. In other words, the A-group element included in the 2nd Mn phase may consist of only Zn or may consist of Zn and an element other than Zn (one or more types of Ga, Sn, Ge, Al, and Co). When the A-group element included in the 2nd Mn phase consists of only Zn, the total content of the A-group element other than Zn included in the 2nd Mn phase is 0. When the A-group element included in the 2nd Mn phase consists of Zn and an element other than Zn, the total content of the A-group element other than Zn included in the 2nd Mn phase is preferably more than 0 and not more than 15 at %, more preferably more than 0 and not more than 10 at %. Note that a type(s) of an element(s) composing the A-group element included in the 2nd Mn phase may be a part of a type(s) of an element(s) composing the A-group element included in the sintered alloy according to the present invention or may be all of the type(s) of the element(s). For example, the A-group element included in the 2nd Mn phase consists of only Zn when the A-group element included in the sintered alloy according to the present invention consists of only Zn, while the A-group element included in the 2nd Mn phase may consist of only Zn or may consist of Zn and one type of element other than Zn when the A-group element included in the sintered alloy according to the present invention consists of Zn and one type of element other than Zn. Additionally, when the A-group element included in the sintered alloy according to the present invention consists of Zn and two types of elements other than Zn, the A-group element included in the 2nd Mn phase may consist of only Zn, may consist of Zn and one type of element other than Zn or may consist of Zn and two types of elements other than Zn. Additionally, when the A-group element included in the sintered alloy according to the present invention consists of Zn and three types of elements other than Zn, the A-group element included in the 2nd Mn phase may consist of only Zn, may consist of Zn and one type of element other than Zn, may consist of Zn and two types of elements other than Zn or may consist of Zn and three types of elements other than Zn.

When the A-group element included in the 2nd Mn phase consists of Zn and an element other than Zn (one or more types of elements selected from Ga, Sn, Ge, Al, and Co), it is preferable that the 2nd Mn phase include the A-group element other than Zn in an atomic ratio that satisfies one or more conditions of Mn:Ga=98:2 to 73:27, Mn:Sn=98.5:1.5 to 74:26, Mn:Ge=98.5:1.5 to 79:21, Mn:Al=98:2 to 49:51, and Mn:Co=96:4 to 51:49. A preferable range of the atomic ratio of Mn and the A-group element other than Zn in the 2nd Mn phase is the same as a preferable range described in regard to the 1st and 3rd to 6th Mn phases. However, the 2nd Mn phase may include the A-group element other than Zn in an atomic ratio that does not satisfy the above-mentioned atomic ratio in addition to the A-group element other than Zn in an atomic ratio that satisfies the above-mentioned atomic ratio.

The condition A2-2 does not mean that the 2nd Mn phase has to include the B-group element. In other words, the 2nd Mn phase may or may not include the B-group element. When the 2nd Mn phase includes the B-group element, the total content of the B-group element included in the 2nd Mn phase is preferably more than 0 and not more than 15 at %, more preferably more than 0 and not more than 10 at %. Note that the 2nd Mn phase does not include the B-group element when the sintered alloy according to the present invention does not include the B-group element, while the 2nd Mn phase may or may not include the B-group element when the sintered alloy according to the present invention includes the B-group element. Additionally, a type(s) of an element(s) composing the B-group element included in the 2nd Mn phase may be a part of a type(s) of an element(s) composing the B-group element included in the sintered alloy according to the present invention or may be all of the type(s) of the element(s). For example, when the B-group element included in the sintered alloy according to the present invention consists of two types of elements, the B-group element included in the 2nd Mn phase may consist of one type of element or may consist of two types of elements. Furthermore, when the B-group element included in the sintered alloy according to the present invention consists of three types of elements, the B-group element included in the 2nd Mn phase may consist of one type of element, may consist of two types of elements or may consist of three types of elements.

The 3rd Mn phase satisfies the following conditions.

[Condition A3-1] The 3rd Mn phase includes Mn and Sn in an atomic ratio of Mn:Sn=98.5:1.5 to 74:26.

[Condition A3-2] The total content of the A-group element other than Sn and the B-group element in the 3rd Mn phase is 20 at % or less. In other words, the total content of Mn and Sn in the 3rd Mn phase is 80 at % or more. Note that “at %” in the condition A3-2 is calculated on the basis of the total number of atoms included in the 3rd Mn phase.

Whether a composition of the 3rd Mn phase (a type and content of an element) falls within a predetermined range or not can be confirmed using an energy dispersive X-ray fluorescence spectrometer.

The 3rd Mn phase satisfies the conditions A3-1 and A3-2 so that the 3rd Mn phase becomes γMn phase or βMn phase that has high toughness, and therefore high mechanical strengths (specifically, high toughness suitable for a sputtering target material) can be imparted to the sintered alloy by the 3rd Mn phase. When the atomic ratio of Mn and Sn in the 3rd Mn phase falls out of the range that Mn:Sn=98.5:1.5 to 74:26 (in other words, Mn/Sn>98.5/1.5 or Mn/Sn<74/26), or the total content of the A-group element other than Sn and the B-group element in the 3rd Mn phase exceeds 20 at %, toughness of the 3rd Mn phase is lowered and the 3rd Mn phase becomes fragile phase.

The atomic ratio of Mn and Sn in the 3rd Mn phase can be appropriately adjusted within the range that Mn:Sn=98.5:1.5 to 74:26, and is preferably Mn:Sn=98.5:1.5 to 76:24, more preferably Mn:Sn=95:5 to 84:16, still more preferably Mn:Sn=93:7 to 85:15.

The total content of the A-group element other than Sn and the B-group element in the 3rd Mn phase can be appropriately adjusted within a range of 20 at % or less, and is preferably 18 at % or less, more preferably 15 at % or less. Note that the lower limit of the total content of the A-group element other than Sn and the B-group element in the 3rd Mn phase is 0.

The condition A3-2 does not mean that the 3rd Mn phase has to include the A-group element other than Sn. In other words, the A-group element included in the 3rd Mn phase may consist of only Sn or may consist of Sn and an element other than Sn (one or more types of Ga, Zn, Ge, Al, and Co). When the A-group element included in the 3rd Mn phase consists of only Sn, the total content of the A-group element other than Sn included in the 3rd Mn phase is 0. When the A-group element included in the 3rd Mn phase consists of Sn and an element other than Sn, the total content of the A-group element other than Sn included in the 3rd Mn phase is preferably more than 0 and not more than 15 at %, more preferably more than 0 and not more than 10 at %. Note that a type(s) of an element(s) composing the A-group element included in the 3rd Mn phase may be a part of a type(s) of an element(s) composing the A-group element included in the sintered alloy according to the present invention or may be all of the type(s) of the element(s). For example, the A-group element included in the 3rd Mn phase consists of only Sn when the A-group element included in the sintered alloy according to the present invention consists of only Sn, while the A-group element included in the 3rd Mn phase may consist of only Sn or may consist of Sn and one type of element other than Sn when the A-group element included in the sintered alloy according to the present invention consists of Sn and one type of element other than Sn. Additionally, when the A-group element included in the sintered alloy according to the present invention consists of Sn and two types of elements other than Sn, the A-group element included in the 3rd Mn phase may consist of only Sn, may consist of Sn and one type of element other than Sn or may consist of Sn and two types of elements other than Sn. Additionally, when the A-group element included in the sintered alloy according to the present invention consists of Sn and three types of elements other than Sn, the A-group element included in the 3rd Mn phase may consist of only Sn, may consist of Sn and one type of element other than Sn, may consist of Sn and two types of elements other than Sn or may consist of Sn and three types of elements other than Sn.

When the A-group element included in the 3rd Mn phase consists of Sn and an element other than Sn (one or more types of elements selected from Ga, Zn, Ge, Al, and Co), it is preferable that the 3rd Mn phase include the A-group element other than Sn in an atomic ratio that satisfies one or more conditions of Mn:Ga=98:2 to 73:27, Mn:Zn=98:2 to 64:36, Mn:Ge=98.5:1.5 to 79:21, Mn:Al=98:2 to 49:51, and Mn:Co=96:4 to 51:49. A preferable range of the atomic ratio of Mn and the A-group element other than Sn in the 3rd Mn phase is the same as a preferable range described in regard to the 1st, 2nd and 4th to 6th Mn phases. However, the 3rd Mn phase may include the A-group element other than Sn in an atomic ratio that does not satisfy the above-mentioned atomic ratio in addition to the A-group element other than Sn in an atomic ratio that satisfies the above-mentioned atomic ratio.

The condition A3-2 does not mean that the 3rd Mn phase has to include the B-group element. In other words, the 3rd Mn phase may or may not include the B-group element. When the 3rd Mn phase includes the B-group element, the total content of the B-group element included in the 3rd Mn phase is preferably more than 0 and not more than 15 at %, more preferably more than 0 and not more than 10 at %. Note that the 3rd Mn phase does not include the B-group element when the sintered alloy according to the present invention does not include the B-group element, while the 3rd Mn phase may or may not include the B-group element when the sintered alloy according to the present invention includes the B-group element. Additionally, a type(s) of an element(s) composing the B-group element included in the 3rd Mn phase may be a part of a type(s) of an element(s) composing the B-group element included in the sintered alloy according to the present invention or may be all of the type(s) of the element(s). For example, when the B-group element included in the sintered alloy according to the present invention consists of two types of elements, the B-group element included in the 3rd Mn phase may consist of one type of element or may consist of two types of elements. Furthermore, when the B-group element included in the sintered alloy according to the present invention consists of three types of elements, the B-group element included in the 3rd Mn phase may consist of one type of element, may consist of two types of elements or may consist of three types of elements.

The 4th Mn phase satisfies the following conditions.

[Condition A4-1] The 4th Mn phase includes Mn and Ge in an atomic ratio of Mn:Ge=98.5:1.5 to 79:21.

[Condition A4-2] The total content of the A-group element other than Ge and the B-group element in the 4th Mn phase is 20 at % or less. In other words, the total content of Mn and Ge in the 4th Mn phase is 80 at % or more. Note that “at %” in the condition A4-2 is calculated on the basis of the total number of atoms included in the 4th Mn phase.

Whether a composition of the 4th Mn phase (a type and content of an element) falls within a predetermined range or not can be confirmed using an energy dispersive X-ray fluorescence spectrometer.

The 4th Mn phase satisfies the conditions A4-1 and A4-2 so that the 4th Mn phase becomes γMn phase or βMn phase that has high toughness, and therefore high mechanical strengths (specifically, high toughness suitable for a sputtering target material) can be imparted to the sintered alloy by the 4th Mn phase. When the atomic ratio of Mn and Ge in the 4th Mn phase falls out of the range that Mn:Ge=98.5:1.5 to 79:21 (in other words, Mn/Ge>98.5/1.5 or Mn/Ge<79/21), or the total content of the A-group element other than Ge and the B-group element in the 4th Mn phase exceeds 20 at %, toughness of the 4th Mn phase is lowered and the 4th Mn phase becomes fragile phase.

The atomic ratio of Mn and Ge in the 4th Mn phase can be appropriately adjusted within the range that Mn:Ge=98.5:1.5 to 79:21, and is preferably Mn:Ge=94:6 to 88:12, more preferably Mn:Ge=93:7 to 89:11.

The total content of the A-group element other than Ge and the B-group element in the 4th Mn phase can be appropriately adjusted within a range of 20 at % or less, and is preferably 18 at % or less, more preferably 15 at % or less. Note that the lower limit of the total content of the A-group element other than Ge and the B-group element in the 4th Mn phase is 0.

The condition A4-2 does not mean that the 4th Mn phase has to include the A-group element other than Ge. In other words, the A-group element included in the 4th Mn phase may consist of only Ge or may consist of Ge and an element other than Ge (one or more types of Ga, Zn, Sn, Al, and Co). When the A-group element included in the 4th Mn phase consists of only Ge, the total content of the A-group element other than Ge included in the 4th Mn phase is 0. When the A-group element included in the 4th Mn phase consists of Ge and an element other than Ge, the total content of the A-group element other than Ge included in the 4th Mn phase is preferably more than 0 and not more than 15 at %, more preferably more than 0 and not more than 10 at %. Note that a type(s) of an element(s) composing the A-group element included in the 4th Mn phase may be a part of a type(s) of an element(s) composing the A-group element included in the sintered alloy according to the present invention or may be all of the type(s) of the element(s). For example, the A-group element included in the 4th Mn phase consists of only Ge when the A-group element included in the sintered alloy according to the present invention consists of only Ge, while the A-group element included in the 4th Mn phase may consist of only Ge or may consist of Ge and one type of element other than Ge when the A-group element included in the sintered alloy according to the present invention consists of Ge and one type of element other than Ge. Additionally, when the A-group element included in the sintered alloy according to the present invention consists of Ge and two types of elements other than Ge, the A-group element included in the 4th Mn phase may consist of only Ge, may consist of Ge and one type of element other than Ge or may consist of Ge and two types of elements other than Ge. Furthermore, when the A-group element included in the sintered alloy according to the present invention consists of Ge and three types of elements other than Ge, the A-group element included in the 4th Mn phase may consist of only Ge, may consist of Ge and one type of element other than Ge, may consist of Ge and two types of elements other than Ge or may consist of Ge and three types of elements other than Ge.

When the A-group element included in the 4th Mn phase consists of Ge and an element other than Ge (one or more types of elements selected from Ga, Zn, Sn, Al, and Co), it is preferable that the 4th Mn phase include the A-group element other than Ge in an atomic ratio that satisfies one or more conditions of Mn:Ga=98:2 to 73:27, Mn:Zn=98:2 to 64:36, Mn:Sn=98.5:1.5 to 74:26, Mn:Al=98:2 to 49:51, and Mn:Co=96:4 to 51:49. A preferable range of the atomic ratio of Mn and the A-group element other than Ge in the 4th Mn phase is the same as a preferable range described in regard to the 1st to 3rd, 5th and 6th Mn phases. However, the 4th Mn phase may include the A-group element other than Ge in an atomic ratio that does not satisfy the above-mentioned atomic ratio in addition to the A-group element other than Ge in an atomic ratio that satisfies the above-mentioned atomic ratio.

The condition A4-2 does not mean that the 4th Mn phase has to include the B-group element. In other words, the 4th Mn phase may or may not include the B-group element. When the 4th Mn phase includes the B-group element, the total content of the B-group element included in the 4th Mn phase is preferably more than 0 and not more than 15 at %, more preferably more than 0 and not more than 10 at %. Note that the 4th Mn phase does not include the B-group element when the sintered alloy according to the present invention does not include the B-group element, while the 4th Mn phase may or may not include the B-group element when the sintered alloy according to the present invention includes the B-group element. Additionally, a type(s) of an element(s) composing the B-group element included in the 4th Mn phase may be a part of a type(s) of an element(s) composing the B-group element included in the sintered alloy according to the present invention or may be all of the type(s) of the element(s). For example, when the B-group element included in the sintered alloy according to the present invention consists of two types of elements, the B-group element included in the 4th Mn phase may consist of one type of element or may consist of two types of elements. Furthermore, when the B-group element included in the sintered alloy according to the present invention consists of three types of elements, the B-group element included in the 4th Mn phase may consist of one type of element, may consist of two types of elements or may consist of three types of elements.

The 5th Mn phase satisfies the following conditions.

[Condition A5-1] The 5th Mn phase includes Mn and Al in an atomic ratio of Mn:Al=98:2 to 49:51.

[Condition A5-2] The total content of the A-group element other than Al and the B-group element in the 5th Mn phase is 20 at % or less. In other words, the total content of Mn and Al in the 5th Mn phase is 80 at % or more. Note that “at %” in the condition A5-2 is calculated on the basis of the total number of atoms included in the 5th Mn phase.

Whether a composition of the 5th Mn phase (a type and content of an element) falls within a predetermined range or not can be confirmed using an energy dispersive X-ray fluorescence spectrometer.

The 5th Mn phase satisfies the conditions A5-1 and A5-2 so that the 5th Mn phase becomes γMn phase or βMn phase that has high toughness, and therefore high mechanical strengths (specifically, high toughness suitable for a sputtering target material) can be imparted to the sintered alloy by the 5th Mn phase. When the atomic ratio of Mn and Al in the 5th Mn phase falls out of the range that Mn:Al=98:2 to 49:51 (in other words, Mn/Al>98/2 or Mn/Al<49/51), or the total content of the A-group element other than Al and the B-group element in the 5th Mn phase exceeds 20 at %, toughness of the 5th Mn phase is lowered and the 5th Mn phase becomes fragile phase.

The atomic ratio of Mn and Al in the 5th Mn phase can be appropriately adjusted within the range that Mn:Al=98:2 to 49:51, and is preferably Mn:Al=96:4 to 59:41, more preferably Mn:Al=90:10 to 65:35.

The total content of the A-group element other than Al and the B-group element in the 5th Mn phase can be appropriately adjusted within a range of 20 at % or less, and is preferably 18 at % or less, more preferably 15 at % or less. Note that the lower limit of the total content of the A-group element other than Al and the B-group element in the 5th Mn phase is 0.

The condition A5-2 does not mean that the 5th Mn phase has to include the A-group element other than Al. In other words, the A-group element included in the 5th Mn phase may consist of only Al or may consist of Al and an element other than Al (one or more types of Ga, Zn, Sn, Ge, and Co). When the A-group element included in the 5th Mn phase consists of only Al, the total content of the A-group element other than Al included in the 5th Mn phase is 0. When the A-group element included in the 5th Mn phase consists of Al and an element other than Al, the total content of the A-group element other than Al included in the 5th Mn phase is preferably more than 0 and not more than 15 at %, more preferably more than 0 and not more than 10 at %. Note that a type(s) of an element(s) composing the A-group element included in the 5th Mn phase may be a part of a type(s) of an element(s) composing the A-group element included in the sintered alloy according to the present invention or may be all of the type(s) of the element(s). For example, the A-group element included in the 5th Mn phase consists of only Al when the A-group element included in the sintered alloy according to the present invention consists of only Al, while the A-group element included in the 5th Mn phase may consist of only Al or may consist of Al and one type of element other than Al when the A-group element included in the sintered alloy according to the present invention consists of Al and one type of element other than Al. Additionally, when the A-group element included in the sintered alloy according to the present invention consists of Al and two types of elements other than Al, the A-group element included in the 5th Mn phase may consist of only Al, may consist of Al and one type of element other than Al or may consist of Al and two types of elements other than Al. Additionally, when the A-group element included in the sintered alloy according to the present invention consists of Al and three types of elements other than Al, the A-group element included in the 5th Mn phase may consist of only Al, may consist of Al and one type of element other than Al, may consist of Al and two types of elements other than Al or may consist of Al and three types of elements other than Al.

When the A-group element included in the 5th Mn phase consists of Al and an element other than Al (one or more types of elements selected from Ga, Zn, Sn, Ge, and Co), it is preferable that the 5th Mn phase include the A-group element other than Al in an atomic ratio that satisfies one or more conditions of Mn:Ga=98:2 to 73:27, Mn:Zn=98:2 to 64:36, Mn:Sn=98.5:1.5 to 74:26, Mn:Ge=98.5:1.5 to 79:21, and Mn:Co=96:4 to 51:49. A preferable range of the atomic ratio of Mn and the A-group element other than Al in the 5th Mn phase is the same as a preferable range described in regard to the 1st to 4th, and 6th Mn phases. However, the 5th Mn phase may include the A-group element other than Al in an atomic ratio that does not satisfy the above-mentioned atomic ratio in addition to the A-group element other than Al in an atomic ratio that satisfies the above-mentioned atomic ratio.

The condition A5-2 does not mean that the 5th Mn phase has to include the B-group element. In other words, the 5th Mn phase may or may not include the B-group element. When the 5th Mn phase includes the B-group element, the total content of the B-group element included in the 5th Mn phase is preferably more than 0 and not more than 15 at %, more preferably more than 0 and not more than 10 at %. Note that the 5th Mn phase does not include the B-group element when the sintered alloy according to the present invention does not include the B-group element, while the 5th Mn phase may or may not include the B-group element when the sintered alloy according to the present invention includes the B-group element. Additionally, a type(s) of an element(s) composing the B-group element included in the 5th Mn phase may be a part of a type(s) of an element(s) composing the B-group element included in the sintered alloy according to the present invention or may be all of the type(s) of the element(s). For example, when the B-group element included in the sintered alloy according to the present invention consists of two types of elements, the B-group element included in the 5th Mn phase may consist of one type of element or may consist of two types of elements. Furthermore, when the B-group element included in the sintered alloy according to the present invention consists of three types of elements, the B-group element included in the 5th Mn phase may consist of one type of element, may consist of two types of elements or may consist of three types of elements.

The 6th Mn phase satisfies the following conditions.

[Condition A6-1] The 6th Mn phase includes Mn and Co in an atomic ratio of Mn:Co=96:4 to 51:49.

[Condition A6-2] The total content of the A-group element other than Co and the B-group element in the 6th Mn phase is 20 at % or less. In other words, the total content of Mn and Co in the 6th Mn phase is 80 at % or more. Note that “at %” in the condition A6-2 is calculated on the basis of the total number of atoms included in the 6th Mn phase.

Whether a composition of the 6th Mn phase (a type and content of an element) falls within a predetermined range or not can be confirmed using an energy dispersive X-ray fluorescence spectrometer.

The 6th Mn phase satisfies the conditions A6-1 and A6-2 so that the 6th Mn phase becomes γMn phase or βMn phase that has high toughness, and therefore high mechanical strengths (specifically, high toughness suitable for a sputtering target material) can be imparted to the sintered alloy by the 6th Mn phase. When the atomic ratio of Mn and Co in the 6th Mn phase falls out of the range that Mn:Co=96:4 to 51:49 (in other words, Mn/Co>96/4 or Mn/Co<51/49), or the total content of the A-group element other than Co and the B-group element in the 6th Mn phase exceeds 20 at %, toughness of the 6th Mn phase is lowered and the 6th Mn phase becomes fragile phase.

The atomic ratio of Mn and Co in the 6th Mn phase can be appropriately adjusted within the range that Mn:Co=96:4 to 51:49, and is preferably Mn:Co=83:17 to 64:36, more preferably Mn:Co=80:20 to 70:30.

The total content of the A-group element other than Co and the B-group element in the 6th Mn phase can be appropriately adjusted within a range of 20 at % or less, and is preferably 18 at % or less, more preferably 15 at % or less. Note that the lower limit of the total content of the A-group element other than Co and the B-group element in the 6th Mn phase is 0.

The condition A6-2 does not mean that the 6th Mn phase has to include the A-group element other than Co. In other words, the A-group element included in the 6th Mn phase may consist of only Co or may consist of Co and an element other than Co (one or more types of Ga, Zn, Sn, Ge, and Al). When the A-group element included in the 6th Mn phase consists of only Co, the total content of the A-group element other than Co included in the 6th Mn phase is 0. When the A-group element included in the 6th Mn phase consists of Co and an element other than Co, the total content of the A-group element other than Co included in the 6th Mn phase is preferably more than 0 and not more than 15 at %, more preferably more than 0 and not more than 10 at %. Note that a type(s) of an element(s) composing the A-group element included in the 6th Mn phase may be a part of a type(s) of an element(s) composing the A-group element included in the sintered alloy according to the present invention or may be all of them. For example, the A-group element included in the 6th Mn phase consists of only Co when the A-group element included in the sintered alloy according to the present invention consists of only Co, while the A-group element included in the 6th Mn phase may consist of only Co or may consist of Co and one type of element other than Co when the A-group element included in the sintered alloy according to the present invention consists of Co and one type of element other than Co. Additionally, when the A-group element included in the sintered alloy according to the present invention consists of Co and two types of elements other than Co, the A-group element included in the 6th Mn phase may consist of only Co, may consist of Co and one type of element other than Co or may consist of Co and two types of elements other than Co. Additionally, when the A-group element included in the sintered alloy according to the present invention consists of Co and three types of elements other than Co, the A-group element included in the 6th Mn phase may consist of only Co, may consist of Co and one type of element other than Co, may consist of Co and two types of elements other than Co or may consist of Co and three types of elements other than Co.

When the A-group element included in the 6th Mn phase consists of Co and an element other than Co (one or more types of elements selected from Ga, Zn, Sn, Ge, and Al), it is preferable that the 6th Mn phase include the A-group element other than Co in an atomic ratio that satisfies one or more conditions of Mn:Ga=98:2 to 73:27, Mn:Zn=98:2 to 64:36, Mn:Sn=98.5:1.5 to 74:26, Mn:Ge=98.5:1.5 to 79:21, and Mn:Al=98:2 to 49:51. A preferable range of the atomic ratio of Mn and the A-group element other than Co in the 6th Mn phase is the same as a preferable range described in regard to the 1st to 5th Mn phases. However, the 6th Mn phase may include the A-group element other than Co in an atomic ratio that does not satisfy the above-mentioned atomic ratio in addition to the A-group element other than Co in an atomic ratio that satisfies the above-mentioned atomic ratio.

The condition A6-2 does not mean that the 6th Mn phase has to include the B-group element. In other words, the 6th Mn phase may or may not include the B-group element. When the 6th Mn phase includes the B-group element, the total content of the B-group element included in the 6th Mn phase is preferably more than 0 and not more than 15 at %, more preferably more than 0 and not more than 10 at %. Note that the 6th Mn phase does not include the B-group element when the sintered alloy according to the present invention does not include the B-group element, while the 6th Mn phase may or may not include the B-group element when the sintered alloy according to the present invention includes the B-group element. Additionally, a type(s) of an element(s) composing the B-group element included in the 6th Mn phase may be a part of a type(s) of an element(s) composing the B-group element included in the sintered alloy according to the present invention or may be all of the type(s) of the element(s). For example, when the B-group element included in the sintered alloy according to the present invention consists of two types of elements, the B-group element included in the 6th Mn phase may consist of one type of element or may consist of two types of elements. Furthermore, when the B-group element included in the sintered alloy according to the present invention consists of three types of elements, the B-group element included in the 6th Mn phase may consist of one type of element, may consist of two types of elements or may consist of three types of elements.

In the sintered alloy according to the present invention, it is preferable that the total area percentage of the 1st to 6th Mn phases be 10% or more. This enables high mechanical strengths (specifically, high toughness suitable for a sputtering target material) to be imparted to the sintered alloy. The more the total area percentage of the 1st to 6th Mn phases is increased, the more the toughness of the sintered alloy is enhanced. The total area percentage of the 1st to 6th Mn phases is more preferably 25% or more, still more preferably 28% or more. The upper limit of the total area percentage of the 1st to 6th Mn phases is preferably 100%, more preferably 95%.

“The total area percentage of the 1st to 6th Mn phases” merely means that the areas of the 1st to 6th Mn phases are taken account of, but the areas of Mn phases other than the 1st to 6th Mn phases are not taken account of when the total area percentage of the Mn phases is calculated. Therefore, the sintered alloy according to the present invention may include a Mn phase other than the 1st to 6th Mn phases. The sintered alloy according to the present invention does not have to include all the 1st to 6th Mn phases. For example, when the sintered alloy according to the present invention includes the 1st Mn phase, but does not include the other Mn phases, “the total area percentage of the 1st to 6th Mn phases” means the total area percentage of the 1st Mn phase, while, when the sintered alloy according to the present invention includes the 1st and 2nd Mn phases, but does not include the other Mn phases, “the total area percentage of the 1st to 6th Mn phases” means the total area percentage of the 1st and 2nd Mn phases.

The total area percentage of the 1st to 6th Mn phases is measured as the followings. A specimen is taken from the sintered alloy and a cross section of the specimen is polished. The polished cross section is observed for its microstructure using a scanning electron microscope and an energy dispersive X-ray fluorescence spectrometer. The microstructure observation is carried out for 10 regions, each of which has an area of 60 μm×50 μm. Whether each observed Mn phases corresponds to any of the 1st to 6th Mn phases or not is identified by the energy dispersive X-ray fluorescence spectrometer. The areas of Mn phases, each of which corresponds to any of the 1st to 6th Mn phases, are measured in each 10 regions and the total area of the 1st to 6th Mn phases in the 10 regions is calculated. The total area percentage of the 1st to 6th Mn phases is then calculated according to the formula: the total area of the 1st to 6th Mn phases in the 10 regions/the total area of 10 regions (3000 μm²×10=30000 μm²).

In the sintered alloy according to the present invention, a density of the 1st to 6th Mn phases having sizes of 2 μm or more is preferably one or more per 30000 μm², more preferably one or more per 3000 μm². This enables high mechanical strengths (specifically, high toughness suitable for a sputtering target material) to be imparted to the sintered alloy. The more the sizes of the 1st to 6th Mn phases are increased or the more the density of the 1st to 6th Mn phases is increased, the more the toughness of the sintered alloy according to the present invention is enhanced. As long as the sizes of the 1st to 6th Mn phases, each of which exists at a density of one or more per the predetermined area, are 2 μm or more, the sizes are not particularly limited and are preferably 5 μm or more, more preferably 8 μm or more. The upper limits of the sizes of the 1st to 6th Mn phases are preferably 500 μm, more preferably 400 μm. As long as the number of the 1st to 6th Mn phases having sizes of 2 μm or more is one or more per 30000 pmt when the density of the 1st to 6th Mn phases having sizes of 2 μm or more is one or more per 30000 μm², the number is not particularly limited and is preferably 3 or more per 30000 μm², more preferably 5 or more per 30000 μm². As long as the number of the 1st to 6th Mn phases having sizes of 2 μm or more is one or more per 3000 μm² when the density of the 1st to 6th Mn phases having sizes of 2 μm or more is one or more per 3000 μm², the number is not particularly limited and is preferably 3 or more per 3000 μm², more preferably 5 or more per 3000 μm².

“The 1st to 6th Mn phases having sizes of 2 μm or more” merely means that the number of the 1st to 6th Mn phases is taken account of, but the number of Mn phases other than the 1st to 6th Mn phases is not taken account of when the density of the Mn phases is calculated. Therefore, the sintered alloy according to the present invention may include a Mn phase other than the 1st to 6th Mn phases. The sintered alloy according to the present invention does not have to include all the 1st to 6th Mn phases. For example, when the sintered alloy according to the present invention includes the 1st Mn phase, but does not include the other Mn phases, “the 1st to 6th Mn phases having sizes of 2 μm or more” means the 1st Mn phase having a size of 2 μm or more, while, when the sintered alloy according to the present invention includes the 1st and 2nd Mn phases, but does not include the other Mn phases, “the 1st to 6th Mn phases having sizes of 2 μm or more” means the 1st and 2nd Mn phases having sizes of 2 μm or more.

The density of the 1st to 6th Mn phases having sizes of 2 μm or more is measured as the followings. A specimen is taken from the sintered alloy and a cross section of the specimen is polished. The polished cross section is observed for its microstructure using a scanning electron microscope and an energy dispersive X-ray fluorescence spectrometer. The microstructure observation is carried out for 10 regions, each of which has an area of 60 μm×50 μm. Whether each of observed Mn phases corresponds to any of the 1st to 6th Mn phases or not is identified by the energy dispersive X-ray fluorescence spectrometer. A major axis of a Mn phase (that is, a diameter of a circle circumscribed to a Mn phase) is defined as a size of the Mn phase and the sizes of Mn phases that exist in each 10 regions are measured. In each of the 10 regions, the number of Mn phases, each of which corresponds to any of the 1st to 6th Mn phases and has a size of 2 μm or more, is counted and the total number of the 1st to 6th Mn phases having sizes of 2 μm or more in the 10 regions is calculated. Thus, when the total number of the 1st to 6th Mn phases having sizes of 2 μm or more in the 10 regions is one or more, this is defined as “the density of the 1st to 6th Mn phases having sizes of 2 μm or more is one or more per 30000 μm²”. Additionally, when one or more Mn phases, each of which corresponds to any of the 1st to 6th Mn phases and has a size of 2 μm or more, are observed in all of 10 regions, this is defined as “the density of the 1st to 6th Mn phases having sizes of 2 μm or more is one or more per 3000 μm²”.

As shown in the Examples described below, the size of a Mn phase in the sintered alloy depends on a particle size of a raw material powder such as an atomized powder that is a main constituent of the Mn phase (the raw material powder may be hereinafter referred to as “Mn phase forming raw material powder”), and the range of the particle size of the Mn phase forming raw material powder that was observed in the Example was 2 μm to 500 μm. Especially, many particles, each of which has a particle size of 30 μm to 180 μm, were observed. The number of Mn phases included in the sintered alloy is almost the same as that of particles included in the Mn phase forming raw material powder. In other words, a proportion of Mn phases in the sintered alloy mostly depends on a mixture ratio of the Mn phase forming raw material powder and the other raw material powders. As the inventive examples 56 to 79 shown in Table 5, when a single raw material powder that satisfies the predetermined condition is used, the whole sintered alloy is formed of a Mn phase that corresponds to any of the 1st to 6th Mn phases and therefore the total area percentage of the 1st to 6th Mn phases is 100%.

In the sintered alloy according to the present invention, it is preferable that a flexural strength be 100 MPa or more. The sintered alloy having a flexural strength of 100 MPa or more has high mechanical strengths (specifically, high toughness suitable for a sputtering target material). The more the flexural strength is increased, the more the toughness of the sintered alloy is enhanced. The flexural strength is more preferably 120 MPa or more, still more preferably 130 MPa or more. The upper limit of the flexural strength is, for example, 400 MPa.

The flexural strength is measured as the followings. A specimen with a size of length 4 mm, width 25 mm and thickness 3 mm is cut out by a wire from the sintered alloy and is evaluated by a three-point bending test. A three-point bending test is carried out in such a way that a rolling reduction is applied onto the surface with a size of length 4 mm and width 25 mm with a distance between support points of 20 mm and a stress at the time is then measured. A three-point bending strength is calculated according to the following formula.

A three-point bending strength (MPa)=(3×stress (N)×a distance between support points (mm)/(2×a specimen width (mm)×(a specimen thickness (mm)²)

In the sintered alloy according to the present invention, it is preferable that a relative density be 90% or more. This enables high mechanical strengths (specifically, high toughness suitable for a sputtering target material) to be imparted to the sintered alloy. The more the relative density is increased, the more the toughness of the sintered alloy is enhanced. The relative density is more preferably 95% or more, still more preferably 98% or more.

The relative density of the sintered alloy is measured as the followings. The relative density (%) of the sintered alloy is a value that is measured on the basis of Archimedes method, and is defined as a percentage of a measured density of the sintered alloy to a theoretical density of the sintered alloy (a measured density of the sintered alloy/a theoretical density of the sintered alloy×100). The measured density of the sintered alloy (g/cm³) is calculated by dividing an aerial weight of the sintered alloy by a volume of the sintered alloy (=an underwater weight of the sintered alloy/a water specific gravity at a measured temperature). The theoretical density of the sintered alloy p (g/cm³) is calculated according to the formula: ρ=[(m₁/100)/ρ₁+(m₂/100)/ρ₂+(m₃/100)/ρ₃+ . . . +(mᵢ/100)/ρᵢ]⁻¹. Note that, in the above formula, each of m₁ to mᵢ represents a content (wt %) of a component of the sintered alloy, and each of ρ₁ to ρᵢ represents a density (g/cm³) of a component corresponding to m₁ to mᵢ.

The sintered alloy according to the present invention can be produced by a powder metallurgy process comprising the steps of: mixing raw material powders in a predetermined ratio; compression molding the mixed powders (a powder metallurgical composition) to form a compact (hereinafter referred to as “molding process”); and sintering the compact to form a sintered compact (hereinafter referred to as “sintering process”).

A molding process can be carried out, for example, by filling a powder metallurgical composition into a mold and applying a pressure to them to form a powder compact. Prior to filling a powder metallurgical composition into a mold, a higher fatty acid-based lubricant may be coated on the inner surface of a mold. The higher fatty acid-based lubricant may be a higher fatty acid or may be a metal salt of a higher fatty acid. Examples of the higher fatty acids include stearic acid, palmitic acid and oleic acid, and examples of the metal salts include lithium salts, calcium salts and zinc salts. Specific examples of the higher fatty acid-based lubricants include zinc stearate. A molding process can be carried out using a known molding method such as pressing. A molding pressure is typically 10 to 350 MPa, and a molding temperature is typically 600 to 1550° C.

A sintering process can be carried out, for example, by heating a powder compact obtained in the molding process to sinter it. A sintering temperature is typically 600 to 1550° C., and a sintering time is typically 1 to 10 hours. It is preferable that a sintering atmosphere be an anti-oxidizing atmosphere such as a vacuum atmosphere, an inert gas atmosphere and a nitrogen atmosphere. When two or more types of raw material powders are mixed and sintered, it is easier to control a structural composition in the sintered compact as mass transfer associated with sintering (e.g. diffusion) is reduced more, and therefore a sintering temperature is preferably 1000° C. or less, more preferably 900° C. or less, still more preferably 800° C. or less.

A molding process and a sintering process can be also carried out simultaneously. Examples of the methods in which a molding process and a sintering process are carried out simultaneously include a hot press, hot isostatic pressing, a powder extrusion process and a powder forging process.

A Mn—Ga-based alloy powder can be used as a raw material powder that is a base material of the 1st Mn phase. A Mn—Ga-based alloy powder may include the A-group element other than Ga and/or the B-group element in addition to Mn and Ga. As a raw material powder of the sintered alloy including a 1st Mn phase, only a Mn—Ga-based alloy powder may be used, or a pure metal powder and/or an alloy powder that compensate an element lacking for a target composition in addition to a Mn—Ga-based alloy powder may be used.

A Mn—Ga-based alloy powder that satisfies the following conditions can be used as a Mn—Ga-based alloy powder.

[Condition B1-1] Each of alloy particles composing the Mn—Ga-based alloy powder includes Mn and Ga in an atomic ratio of Mn:Ga=98:2 to 73:27.

[Condition B1-2] The total content of the A-group element other than Ga and the B-group element in each of alloy particles composing the Mn—Ga-based alloy powder is 20 at % or less. In other words, the total content of Mn and Ga in each of alloy particles composing the Mn—Ga-based alloy powder is 80 at % or more. Note that “at %” in the condition B1-2 is calculated on the basis of the total number of atoms included in each of alloy particles composing the Mn—Ga-based alloy powder.

Whether a composition of each of alloy particles composing the Mn—Ga-based alloy powder (a type and content of an element) falls within a predetermined range or not can be confirmed using an energy dispersive X-ray fluorescence spectrometer.

When a 1st Mn phase is formed with a Mn—Ga-based alloy powder and one or more of Mn, Ga, the A-group element other than Ga and the B-group element, which are originated from the other raw material powder, by mass transfer associated with sintering (e.g. diffusion), a Mn—Ga-based alloy powder that does not satisfy one or two of the conditions B1-1 and B1-2 can be used as a Mn—Ga-based alloy powder. Even when an atomic ratio of Mn and Ga in a Mn—Ga-based alloy powder falls out of a range that Mn:Ga=98:2 to 73:27 (in other words, Mn/Ga>98/2 or Mn/Ga<73/27), an atomic ratio of Mn and Ga in a Mn phase can be allowed to be in a range that Mn:Ga=98:2 to 73:27 by mass transfer associated with sintering (e.g. diffusion). Additionally, even when the total content of the A-group element other than Ga and the B-group element in a Mn—Ga-based alloy powder exceeds 20 at %, the total content of the A-group element other than Ga and the B-group element in a Mn phase can be allowed to be 20 at % or less by mass transfer associated with sintering (e.g. diffusion).

A Mn—Zn-based alloy powder can be used as a raw material powder that is a base material of the 2nd Mn phase. A Mn—Zn-based alloy powder may include the A-group element other than Zn and/or the B-group element in addition to Mn and Zn. As a raw material powder of the sintered alloy including a 2nd Mn phase, only a Mn—Zn-based alloy powder may be used, or a pure metal powder and/or an alloy powder that compensate an element lacking for a target composition in addition to a Mn—Zn-based alloy powder may be used.

A Mn—Zn-based alloy powder that satisfies the following conditions can be used as a Mn—Zn-based alloy powder.

[Condition B2-1] Each of alloy particles composing the Mn—Zn-based alloy powder includes Mn and Zn in an atomic ratio of Mn:Zn=98:2 to 64:36.

[Condition B2-2] The total content of the A-group element other than Zn and the B-group element in each of alloy particles composing the Mn—Zn-based alloy powder is 20 at % or less. In other words, the total content of Mn and Zn in each of alloy particles composing the Mn—Zn-based alloy powder is 80 at % or more. Note that “at %” in the condition B2-2 is calculated on the basis of the total number of atoms included in each of alloy particles composing the Mn—Zn-based alloy powder.

Whether a composition of each of alloy particles composing the Mn—Zn-based alloy powder (a type and content of an element) falls within a predetermined range or not can be confirmed using an energy dispersive X-ray fluorescence spectrometer.

When a 2nd Mn phase is formed with a Mn—Zn-based alloy powder and one or more of Mn, Zn, the A-group element other than Zn and the B-group element, which are originated from the other raw material powder, by mass transfer associated with sintering (e.g. diffusion), a Mn—Zn-based alloy powder that does not satisfy one or two of the conditions B2-1 and B2-2 can be used as a Mn—Zn-based alloy powder. Even when an atomic ratio of Mn and Zn in a Mn—Zn-based alloy powder falls out of a range that Mn:Zn=98:2 to 64:36 (in other words, Mn/Zn>98/2 or Mn/Zn<64/36), an atomic ratio of Mn and Zn in a Mn phase can be allowed to be in a range that Mn:Zn=98:2 to 64:36 by mass transfer associated with sintering (e.g. diffusion). Additionally, even when the total content of the A-group element other than Zn and the B-group element in a Mn—Zn-based alloy powder exceeds 20 at %, the total content of the A-group element other than Zn and the B-group element in a Mn phase can be allowed to be 20 at % or less by mass transfer associated with sintering (e.g. diffusion).

A Mn—Sn-based alloy powder can be used as a raw material powder that is a base material of the 3rd Mn phase. A Mn—Sn-based alloy powder may include the A-group element other than Sn and/or the B-group element in addition to Mn and Sn. As a raw material powder of the sintered alloy including a 3rd Mn phase, only a Mn—Sn-based alloy powder may be used, or a pure metal powder and/or an alloy powder that compensate an element lacking for a target composition in addition to a Mn—Sn-based alloy powder may be used.

A Mn—Sn-based alloy powder that satisfies the following conditions can be used as a Mn—Sn-based alloy powder.

[Condition B3-1] Each of alloy particles composing the Mn—Sn-based alloy powder includes Mn and Sn in an atomic ratio of Mn:Sn=98.5:1.5 to 74:26.

[Condition B3-2] The total content of the A-group element other than Sn and the B-group element in each of alloy particles composing the Mn—Sn-based alloy powder is 20 at % or less. In other words, the total content of Mn and Sn in each of alloy particles composing the Mn—Sn-based alloy powder is 80 at % or more. Note that “at %” in the condition B3-2 is calculated on the basis of the total number of atoms included in each of alloy particles composing the Mn—Sn-based alloy powder.

Whether a composition of each of alloy particles composing the Mn—Sn-based alloy powder (a type and content of an element) falls within a predetermined range or not can be confirmed using an energy dispersive X-ray fluorescence spectrometer.

When a 3rd Mn phase is formed with a Mn—Sn-based alloy powder and one or more of Mn, Sn, the A-group element other than Sn and the B-group element, which are originated from the other raw material powder, by mass transfer associated with sintering (e.g. diffusion), a Mn—Sn-based alloy powder that does not satisfy one or two of the conditions B3-1 and B3-2 can be used as a Mn—Sn-based alloy powder. Even when an atomic ratio of Mn and Sn in a Mn—Sn-based alloy powder falls out of a range that Mn:Sn=98.5:1.5 to 74:26 (in other words, Mn/Sn>98.5/1.5 or Mn/Sn<74/26), an atomic ratio of Mn and Sn in a Mn phase can be allowed to be in a range that Mn:Sn=98.5:1.5 to 74:26 by mass transfer associated with sintering (e.g. diffusion). Additionally, even when the total content of the A-group element other than Sn and the B-group element in a Mn—Sn-based alloy powder exceeds 20 at %, the total content of the A-group element other than Sn and the B-group element in a Mn phase can be allowed to be 20 at % or less by mass transfer associated with sintering (e.g. diffusion).

A Mn—Ge-based alloy powder can be used as a raw material powder that is a base material of the 4th Mn phase. A Mn—Ge-based alloy powder may include the A-group element other than Ge and/or the B-group element in addition to Mn and Ge. As a raw material powder of the sintered alloy including a 4th Mn phase, only a Mn—Ge-based alloy powder may be used, or a pure metal powder and/or an alloy powder that compensate an element lacking for a target composition in addition to a Mn—Ge-based alloy powder may be used.

A Mn—Ge-based alloy powder that satisfies the following conditions can be used as a Mn—Ge-based alloy powder.

[Condition B4-1] Each of alloy particles composing the Mn—Ge-based alloy powder includes Mn and Ge in an atomic ratio of Mn:Ge=98.5:1.5 to 79:21.

[Condition B4-2] The total content of the A-group element other than Ge and the B-group element in each of alloy particles composing the Mn—Ge-based alloy powder is 20 at % or less. In other words, the total content of Mn and Ge in each of alloy particles composing the Mn—Ge-based alloy powder is 80 at % or more. Note that “at %” in the condition B4-2 is calculated on the basis of the total number of atoms included in each of alloy particles composing the Mn—Ge-based alloy powder.

Whether a composition of each of alloy particles composing the Mn—Ge-based alloy powder (a type and content of an element) falls within a predetermined range or not can be confirmed using an energy dispersive X-ray fluorescence spectrometer.

When a 4th Mn phase is formed with a Mn—Ge-based alloy powder and one or more of Mn, Ge, the A-group element other than Ge and the B-group element, which are originated from the other raw material powder, by mass transfer associated with sintering (e.g. diffusion), a Mn—Ge-based alloy powder that does not satisfy one or two of the conditions B4-1 and B4-2 can be used as a Mn—Ge-based alloy powder. Even when an atomic ratio of Mn and Ge in a Mn—Ge-based alloy powder falls out of a range that Mn:Ge=98.5:1.5 to 79:21 (in other words, Mn/Ge>98.5/1.5 or Mn/Ge<79/21), an atomic ratio of Mn and Ge in a Mn phase can be allowed to be in a range that Mn:Ge=98.5:1.5 to 79:21 by mass transfer associated with sintering (e.g. diffusion). Additionally, even when the total content of the A-group element other than Ge and the B-group element in a Mn—Ge-based alloy powder exceeds 20 at %, the total content of the A-group element other than Ge and the B-group element in a Mn phase can be allowed to be 20 at % or less by mass transfer associated with sintering (e.g. diffusion).

A Mn—Al-based alloy powder can be used as a raw material powder that is a base material of the 5th Mn phase. A Mn—Al-based alloy powder may include the A-group element other than Al and/or the B-group element in addition to Mn and Al. As a raw material powder of the sintered alloy including a 5th Mn phase, only a Mn—Al-based alloy powder may be used, or a pure metal powder and/or an alloy powder that compensate an element lacking for a target composition in addition to a Mn—Al-based alloy powder may be used.

A Mn—Al-based alloy powder that satisfies the following conditions can be used as a Mn—Al-based alloy powder.

[Condition B5-1] Each of alloy particles composing the Mn—Al-based alloy powder includes Mn and Al in an atomic ratio of Mn:Al=98:2 to 49:51.

[Condition B5-2] The total content of the A-group element other than Al and the B-group element in each of alloy particles composing the Mn—Al-based alloy powder is 20 at % or less. In other words, the total content of Mn and Al in each of alloy particles composing the Mn—Al-based alloy powder is 80 at % or more. Note that “at %” in the condition B5-2 is calculated on the basis of the total number of atoms included in each of alloy particles composing the Mn—Al-based alloy powder.

Whether a composition of each of alloy particles composing the Mn—Al-based alloy powder (a type and content of an element) falls within a predetermined range or not can be confirmed using an energy dispersive X-ray fluorescence spectrometer.

When a 5th Mn phase is formed with a Mn—Al-based alloy powder and one or more of Mn, Al, the A-group element other than Al and the B-group element, which are originated from the other raw material powder, by mass transfer associated with sintering (e.g. diffusion), a Mn—Al-based alloy powder that does not satisfy one or two of the conditions B5-1 and B5-2 can be used as a Mn—Al-based alloy powder. Even when an atomic ratio of Mn and Al in a Mn—Al-based alloy powder falls out of a range that Mn:Al=98:2 to 49:51 (in other words, Mn/Al>98/2 or Mn/Al<49/51), an atomic ratio of Mn and Al in a 5th Mn phase can be allowed to be in a range that Mn:Al=98:2 to 49:51 by mass transfer associated with sintering (e.g. diffusion). Even when the total content of the A-group element other than Al and the B-group element in a Mn—Al-based alloy powder exceeds 20 at %, the total content of the A-group element other than Al and the B-group element in a Mn phase can be allowed to be 20 at % or less by mass transfer associated with sintering (e.g. diffusion).

A Mn—Co-based alloy powder can be used as a raw material powder that is a base material of the 6th Mn phase. A Mn—Co-based alloy powder may include the A-group element other than Co and/or the B-group element in addition to Mn and Co. As a raw material powder of the sintered alloy including a 6th Mn phase, only a Mn—Co-based alloy powder may be used, or a pure metal powder and/or an alloy powder that compensate an element lacking for a target composition in addition to a Mn—Co-based alloy powder may be used.

A Mn—Co-based alloy powder that satisfies the following conditions can be used as a Mn—Co-based alloy powder.

[Condition B6-1] Each of alloy particles composing the Mn—Co-based alloy powder includes Mn and Co in an atomic ratio of Mn:Co=96:4 to 51:49.

[Condition B6-2] The total content of the A-group element other than Co and the B-group element in each of alloy particles composing the Mn—Co-based alloy powder is 20 at % or less. In other words, the total content of Mn and Co in each of alloy particles composing the Mn—Co-based alloy powder is 80 at % or more. Note that “at %” in the condition B6-2 is calculated on the basis of the total number of atoms included in each of alloy particles composing the Mn—Co-based alloy powder.

Whether a composition of each of alloy particles composing the Mn—Co-based alloy powder (a type and content of an element) falls within a predetermined range or not can be confirmed using an energy dispersive X-ray fluorescence spectrometer.

When a 6th Mn phase is formed with a Mn—Co-based alloy powder and one or more of Mn, Co, the A-group element other than Co and the B-group element, which are originated from the other raw material powder, by mass transfer associated with sintering (e.g. diffusion), a Mn—Co-based alloy powder that does not satisfy one or two of the conditions B6-1 and B6-2 can be used as a Mn—Co-based alloy powder. Even when an atomic ratio of Mn and Co in a Mn—Co-based alloy powder falls out of a range that Mn:Co=96:4 to 51:49 (in other words, Mn/Co>96/4 or Mn/Co<51/49), an atomic ratio of Mn and Co in a 6th Mn phase can be allowed to be in a range that Mn:Co=96:4 to 51:49 by mass transfer associated with sintering (e.g. diffusion). Additionally, even when the total content of the A-group element other than Co and the B-group element in a Mn—Co-based alloy powder exceeds 20 at %, the total content of the A-group element other than Co and the B-group element in a Mn phase can be allowed to be 20 at % or less by mass transfer associated with sintering (e.g. diffusion).

A sputtering target material according to the present invention comprises a sintered alloy according to the present invention. A sputtering target material according to the present invention can be produced by processing the sintered alloy according to the present invention to a desired shape according to a conventional method. The sintered alloy according to the present invention is suitable as a material for a sputtering target material because of having high mechanical strengths (specifically, high toughness suitable for a sputtering target material). According to the sputtering target material comprising the sintered alloy according to the present invention, occurrence of cracking during deposition by sputtering can be prevented.

### Examples

The present invention will be described more specifically with examples below.

In the inventive examples 1 to 55, raw material powders shown in Tables 1 to 4 are combined in the ratio shown in Tables 1 to 4 and mixed for 30 minutes using a V-type mixer, and thereby preparing them to obtain alloy compositions shown in Tables 1 to 4, followed by degassing and charging into a steel can with an outer diameter 220 mm, an inner diameter 210 mm and a length 200 mm. Note that a raw material powder was made as the followings. A raw material to be melted was weighed and melted by induction heating in a refractory crucible under reduced pressure of Ar gas atmosphere or under vacuum atmosphere, followed by tapping from a nozzle with a diameter of 8 mm of the bottom of the crucible and atomizing with Ar gas. Rude powders with particle sizes of 500 μm or more that is not suitable for molding were removed from obtained atomized powders and a gas-atomized powder after the removal was used as a raw material powder.

The aforementioned powder-filled billet was sintered by hot isostatic pressing in the condition of a molding temperature described in Tables 1 to 4, a pressure of 120 MPa and a retention time of 3 hours to make a sintered compact. A solidified compact made by the aforementioned method was processed by wire cutting, lathe working and surface grinding to a disc shape with a diameter of 180 mm and a thickness of 7 mm to produce a sputtering target material. Note that, when two or more types of powders are mixed and sintered, it is easier to control composition percentages of a structure in the sintered compact as diffusion is prevented more, and therefore a molding temperature was 1000° C. or less, desirably 900° C. or less, more desirably 800° C. or less.

In the inventive examples 1 to 37 and 55, as a raw material powder that is a base material of the Mn phases (the raw material powder may be hereinafter referred to as “Mn phase forming raw material powder”), one or more types of:

a Mn—Ga-based alloy powder that satisfies the condition B1-1 and condition B1-2;

a Mn—Zn-based alloy powder that satisfies the condition B2-1 and condition B2-2;

a Mn—Sn-based alloy powder that satisfies the condition B3-1 and condition B3-2;

a Mn—Ge-based alloy powder that satisfies the condition B4-1 and condition B4-2;

a Mn—Al-based alloy powder that satisfies the condition B5-1 and condition B5-2; and

a Mn—Co-based alloy powder that satisfies the condition B6-1 and condition B6-2 were used to produce a sintered alloy having in its microstructure one or more types of Mn phases of:

a 1st Mn phase that satisfies the condition A1-1 and condition A1-2;

a 2nd Mn phase that satisfies the condition A2-1 and condition A2-2;

a 3rd Mn phase that satisfies the condition A3-1 and condition A3-2;

a 4th Mn phase that satisfies the condition A4-1 and condition A4-2;

a 5th Mn phase that satisfies the condition A5-1 and condition A5-2; and

a 6th Mn phase that satisfies the condition A6-1 and condition A6-2.

Because mass transfer associated with sintering (e.g. diffusion) is occurred, a Mn phase is not formed of only the Mn phase forming raw material powder. In other words, a Mn phase may be formed of the Mn phase forming raw material powder and one or more of Mn, the A-group element and the B-group element, which are originated from the other raw material powders, by mass transfer associated with sintering (e.g. diffusion).

In the inventive examples 38 to 54, as a raw material powder that is a base material of the Mn phases (the raw material powder may be hereinafter referred to as “Mn phase forming raw material powder”), one or more types of:

a Mn—Ga-based alloy powder that does not satisfy one or two of the condition B1-1 and condition B1-2;

a Mn—Zn-based alloy powder that does not satisfy one or two of the condition B2-1 and condition B2-2;

a Mn—Sn-based alloy powder that does not satisfy one or two of the condition B3-1 and condition B3-2;

a Mn—Ge-based alloy powder that does not satisfy one or two of the condition B4-1 and condition B4-2;

a Mn—Al-based alloy powder that does not satisfy one or two of the condition B5-1 and condition B5-2;

a Mn—Co-based alloy powder that does not satisfy one or two of the condition B6-1 and condition B6-2 were used to produce a sintered alloy having in its microstructure one or more types of Mn phases of:

a 1st Mn phase that satisfies the condition A1-1 and condition A1-2;

a 2nd Mn phase that satisfies the condition A2-1 and condition A2-2;

a 3rd Mn phase that satisfies the condition A3-1 and condition A3-2;

a 4th Mn phase that satisfies the condition A4-1 and condition A4-2;

a 5th Mn phase that satisfies the condition A5-1 and condition A5-2; and

a 6th Mn phase that satisfies the condition A6-1 and condition A6-2.

Even when an atomic ratio of Mn and the A-group element in the Mn phase forming raw material powder falls out of a desired range, an atomic ratio of Mn and the A-group element in the Mn phase is allowed to be in a desired range by mass transfer associated with sintering (e.g. diffusion). Note that the sintered alloys in the inventive examples 49 to 54 includes a Mn phase other than the 1st to 6th Mn phases (underlined part) in addition to one or more types of the 1st to 6th Mn phases.

In the inventive examples 56 to 79 shown in Table 5, a raw material to be melted was weighed and melted by induction heating in a refractory crucible under reduced pressure of Ar gas atmosphere or under vacuum atmosphere, followed by tapping from a nozzle with a diameter of 8 mm of the bottom of the crucible and atomizing with Ar gas. Rude powders with particle sizes of 500 μm or more that is not suitable for molding were removed from obtained atomized powders and a gas-atomized powder after the removal was used as a raw material powder. The raw material powder was degassed and charged into a steel can with an outer diameter 220 mm, an inner diameter 210 mm and a length 200 mm. The aforementioned powder-filled billet was sintered by hot isostatic pressing in the condition of a molding temperature described in Table 5, a pressure of 120 MPa and a retention time of 4 hours to make a sintered compact. A solidified compact made by the aforementioned method was processed by wire cutting, lathe working and surface grinding to a disc shape with a diameter of 180 mm and a thickness of 7 mm to produce a sputtering target material.

Note that a raw material powder is not limited to an atomized powder. A sintering method may be atmospheric sintering, vacuum sintering, HIP, hot press, SPS, hot extrusion and the like.

For the inventive examples 1 to 79 and the comparative examples 80 to 87, the numbers, sizes, total area percentages, flexural strengths and relative densities of the 1st to 6th Mn phases were evaluated as described below.

[Numbers] A specimen was taken from an end part of the sputtering target material and a cross section of the specimen was polished. The polished cross section was observed for its microstructure using a scanning electron microscope (Scanning electron microscope JSM-6490LV manufactured by JEOL Ltd.) and an energy dispersive X-ray fluorescence spectrometer (Energy dispersive X-ray fluorescence spectrometer 7914 manufactured by OXFORD INSTRUMENTS). The microstructure observation was carried out for 10 regions, each of which had an area of 60 μm×50 μm. Whether each of observed Mn phases corresponded to any of the 1st to 6th Mn phases or not was identified by the energy dispersive X-ray fluorescence spectrometer.

As a result, one or more Mn phases, each of which corresponded to any of the 1st to 6th Mn phases, were observed in every 10 areas in the sintered alloys of the inventive examples 1 to 55. On the other hand, no Mn phase corresponding to any of the 1st to 6th Mn phases was observed in any of 10 areas in the sintered alloys of the comparative examples 80 to 87. Note that, in respect to “Numbers” in Tables 1 to 4 and Table 6, “A” means that one or more Mn phases, each of which corresponded to any of the 1st to 6th Mn phases, were observed in every 10 areas and “B” means that no Mn phase corresponding to any of the 1st to 6th Mn phases was observed in any of 10 areas.

[Sizes] A specimen was taken from an end part of the sputtering target material and a cross section of the specimen was polished. The polished cross section was observed for its microstructure using a scanning electron microscope (Scanning electron microscope JSM-6490LV manufactured by JEOL Ltd.) and an energy dispersive X-ray fluorescence spectrometer (Energy dispersive X-ray fluorescence spectrometer 7914 manufactured by OXFORD INSTRUMENTS). The microstructure observation was carried out for 10 regions, each of which had an area of 60 μm×50 μm. Whether each of observed Mn phases corresponded to any of the 1st to 6th Mn phases or not was identified by the energy dispersive X-ray fluorescence spectrometer. A major axis of a Mn phase (that is, a diameter of a circle circumscribed to a Mn phase) was defined as a size of the Mn phase and the sizes of Mn phases that exist in each 10 regions were measured.

As the result, one or more Mn phases, each of which corresponded to any of the 1st to 6th Mn phases and had a size of 2 μm or more, were observed in every 10 regions in the sintered alloys of the inventive examples 1 to 55. On the other hand, no Mn phase corresponding to any of the 1st to 6th Mn phases and having a size of 2 μm or more was observed in any of 10 regions in the sintered alloys of the comparative examples 80 to 87. Note that, in respect to “Sizes” in Tables 1 to 4 and Table 6, “S” means that one or more Mn phase, each of which corresponded to any of the 1st to 6th Mn phases and had a size of 30 μm to 180 μm, were observed in every 10 regions, “A” means that one or more Mn phases, each of which corresponded to any of the 1st to 6th Mn phases and had a size of 2 μm to 500 μm, were observed in every 10 regions and “B” means that no Mn phase corresponding to any of the 1st to 6th Mn phases and having a size of 2 μm or more was observed in any of 10 regions (that is, only a Mn phase having a size of less than 2 μm was observed in every 10 regions).

[Total area percentage] A specimen was taken from an end part of the sputtering target material and a cross section of the specimen was polished. The polished cross section was observed for its microstructure using a scanning electron microscope (Scanning electron microscope JSM-6490LV manufactured by JEOL Ltd.) and an energy dispersive X-ray fluorescence spectrometer (Energy dispersive X-ray fluorescence spectrometer 7914 manufactured by OXFORD INSTRUMENTS). The microstructure observation was carried out for 10 regions, each of which had an area of 60 μm×50 μm. Whether each of observed Mn phases corresponded to any of the 1st to 6th Mn phases or not was identified by the energy dispersive X-ray fluorescence spectrometer. The areas of Mn phases that corresponded to any of the 1st to 6th Mn phases are measured in each 10 regions and the total area of the 1st to 6th Mn phases in the 10 regions was calculated. The total area percentage of the 1st to 6th Mn phases was then calculated according to the formula: the total area of the 1st to 6th Mn phases in the 10 regions/the total area of 10 regions (3000 μm²×10).

As the result, the total area percentage of the 1st to 6th Mn phases was 10% or more in the sintered alloys of the inventive examples 1 to 55. On the other hand, the total area percentage of the 1st to 6th Mn phases was less than 10% in the sintered alloys in the comparative examples 80 to 87. Note that, in respect to “Percentages” in Tables 1 to 4 and Table 6, “A” means that the total area percentage of the 1st to 6th Mn phases was 10% or more and “B” means that the total area percentage of the 1st to 6th Mn phases was less than 10%.

As described above, observations of microstructures of the sintered alloys in the inventive examples 56 to 79 were carried out. Since a single raw material powder that was one type of Mn—Ga-based alloy powder that satisfies the conditions B1-1 and B1-2, Mn—Zn-based alloy powder that satisfies the conditions B2-1 and B2-2, Mn—Sn-based alloy powder that satisfies the conditions B3-1 and B3-2, Mn—Ge-based alloy powder that satisfies the conditions B4-1 and B4-2, Mn—Al-based alloy powder that satisfies the conditions B5-1 and B5-2, and Mn—Co-based alloy powder that satisfies the conditions B6-1 and B6-2 was used in the inventive examples 56 to 79, the whole sintered alloy was formed of a Mn phase corresponding to any of the 1st to 6th Mn phases, and the total area percentages of the 1st to 6th Mn phases was therefore 100%.

[Relative densities] The relative density (%) of the sintered alloy is a value that is measured on the basis of Archimedes method, and is defined as a percentage of a measured density of the sintered alloy to a theoretical density of the sintered alloy (a measured density of the sintered alloy/a theoretical density of the sintered alloy×100). The measured density of the sintered alloy (g/cm³) was calculated by dividing an aerial weight of the sintered alloy by a volume of the sintered alloy (=an underwater weight of the sintered alloy/a water specific gravity at a measured temperature). The theoretical density of the sintered alloy ρ (g/cm³) was calculated according to the formula: ρ=[(m₁/100)/ρ₁+(m₂/100)/ρ₂+(m₃/100)/ρ₃+ . . . +(mᵢ/100)/ρᵢ]⁻¹. Note that, in the above formula, each of m₁ to mᵢ represents a content (wt %) of a component of the sintered alloy, and each of ρ₁ to ρᵢ represents a density (g/cm³) of a component corresponding to m₁ to mᵢ.

As the result, the relative densities of the sintered alloys in the inventive examples 1 to 79 and the sintered alloys in the comparative examples 80 to 87 were all 90% or more.

[Flexural strengths] The flexural strength is measured as the followings. A specimen with a size of length 4 mm, width 25 mm and thickness 3 mm was cut out by a wire from the sintered alloy, and was evaluated by a three-point bending test. A three-point bending test was carried out in such a way that a rolling reduction was applied onto the surface with a size of length 4 mm and width 25 mm with a distance between support points of 20 mm and a stress at the time was then measured. A three-point bending strength was calculated according to the following formula.

A three-point bending strength (MPa)=(3×stress (N)×a distance between support points (mm)/(2×a specimen width (mm)×(a specimen thickness (mm)²)

As the result, the flexural strengths of the sintered alloys in the inventive examples 1 to 79 were 100 MPa or more. On the other hand, the flexural strengths of the sintered alloys in the comparative examples 80 to 87 were less than 100 MPa.

TABLE 1

| | Alloy | | | | | Molding | |
|---|---|---|---|---|---|---|---|
| | composition | A-group element | B-group element | Mn | Raw material powder (at %) | temperature | |
| No | (at %) | amount (at %) | amount (at %) | amount (at %) | ( ) indicates mixing percentage. | (° C.) | Note |
| 1 | Co—33Mn—33Ge | 66 | 0 | 33 | Mn—1.5Ge(30), pure Ge(38), pure Co(32) | 900 | Inventive examples |
| 2 | Fe—33Mn—33Ge | 33 | 34 | 33 | Mn—6Ge(32), pure Ge(10), Fe—3Ge(36), pure Fe(22) | 900 | |
| 3 | Ni—33Mn—33Ge | 33 | 34 | 33 | Mn—12Ge(35), pure Ge(33), pure Ni(32) | 900 | |
| 4 | Co—10Fe—20Mn—13Cr—33Ge | 57 | 23 | 20 | Mn—21Ge(24), Co—6Ge(25), pure Ge(31), pure Fe(9), | 900 | |
| | | | | | pure Cr(11) | | |
| 5 | Cu—10Zn—3Ru—20Mn—5V—3Nb—20Ge | 25 | 45 | 20 | Mn—20Ge(1), Mn—5Zn(18), Cu—15V(33), pure Cu(16), | 900 | |
| | | | | | pure Ru(5), pure Nb(4), pure Ge(23) | | |
| 6 | Co—33Mn—10Ge—23Sn | 67 | 0 | 33 | Mn—10Ge(10), Mn—5Sn(18), pure Ge(8), pure Sn(36), | 800 | |
| | | | | | pure Co(28) | | |
| 7 | Fe—50Mn—5Ge—5Ga | 10 | 57 | 33 | Mn—12Ge(42), Mn—27Ga(18), pure Fe(40) | 700 | |
| 8 | Cu—20Mn—10Ta—3Ti—10Ge—15Al | 25 | 55 | 20 | Mn—10Ge(10), Mn—5Al(8), pure Al(6), pure Ge(9), | 800 | |
| | | | | | pure Ti(2), pure Cu(39), pure Ta(26) | | |
| 9 | Co—33Mn—33Ge | 67 | 0 | 33 | (Mn—1.5Ge)—10Co(33), pure Ge(38), pure Co(29) | 950 | |
| 10 | Co—33Mn—10Ge—1Ti—1Zr | 65 | 2 | 33 | (Mn—10Ge)—5Ti—5Zr(20), pure Ge(10), pure Co(55), | 800 | |
| | | | | | pure Mn(15) | | |
| 11 | Fe—25Co—25Mn—25Ge | 50 | 25 | 25 | (Mn—10Ge)—5Co—5Fe(23), pure Ge(27), pure Mn(5), | 800 | |
| | | | | | Fe—50Co(45) | | |
| 12 | Fe—33Mn—1Ge—1Zn—1Sn—1Ga—1Al—1Co | 5 | 62 | 33 | Mn—21Ge(5), Mn—37Zn(3), Mn—24Sn(5), Mn—27Ga(5), | 900 | |
| | | | | | Mn—49Co(2), Mn—51Al(1), Fe—30Mn(62), pure Fe(17) | | |
| 13 | Co—33Mn—33Zn | 67 | 0 | 33 | Mn—2Zn(31), pure Zn(35), pure Co(34) | 600 | |
| 14 | Co—1Rh—1Pd—1Ag—33Mn—33Zn | 64 | 3 | 33 | Mn—20Zn(39), pure Zn(27), Rh(1), Pd(1), Ag(2), | 600 | |
| | | | | | pure Co(30) | | |
| 15 | Mn—33Zn—33Si | 33 | 33 | 34 | Mn—33Zn(60), pure Zn(22), pure Si(18) | 700 | |

| | | | Mn phase in the sintered alloy | | | | | |
|---|---|---|---|---|---|---|---|---|
| | Flexural strength | Relative density | Ratio of | A-group element other than the left + | | | Area | |
| No | (MPa) | (%) | Mn and A-group element | B-group element (at %) | Size | Number | percentage | Note |
| 1 | 150 | 97 | Mn:Ge = 98:2 | Co: 2 | A | A | A | Inventive examples |
| 2 | 140 | 103 | Mn:Ge = 94:6 | — | S | A | A | |
| 3 | 150 | 98 | Mn:Ge = 94:15 | Ni: 4 | S | A | A | |
| 4 | 120 | 99 | Mn:Ge = 79:21 | Co: 10, Cr: 1, Fe: 1 | S | A | A | |
| 5 | 100 | 100 | Mn:Ge = 79:21 | Cu: 3, V: 1 | A | A | A | |
| | | | Mn:Zn = 95:5 | Nb: 1, Ge: 2 | | | | |
| 6 | 100 | 100 | Mn:Ge = 89:11 | Sn: 1 | A | A | A | |
| | | | Mn:Sn = 92:8 | Co: 8 | | | | |
| 7 | 100 | 92 | Mn:Ge = 90:10 | — | A | A | A | |
| | | | Mn:Sn = 76:24 | Fe: 1 | | | | |
| 8 | 100 | 95 | Mn:Ge = 85:15 | Al: 2, Ta: 3 | S | A | A | |
| | | | Mn:Al = 90:10 | Ti: 3, Ta: 1 | | | | |
| 9 | 100 | 102 | Mn:Ge = 97:3 | Co: 20 | S | A | A | |
| 10 | 130 | 99 | Mn:Ge = 85:15 | Ti: 4, Zr: 4, Co: 10 | S | A | A | |
| 11 | 100 | 97 | Mn:Ge = 87:13 | Co: 5, Fe: 5 | S | A | A | |
| 12 | 150 | 100 | Mn:Ge = 87:13 | Zn: 1, Al: 2 | A | A | A | |
| | | | Mn:Zn = 75:35 | Sn: 2, Ga: 2 | | | | |
| | | | Mn:Sn = 80:20 | Zn: 1 | | | | |
| | | | Mn:Ga = 75:25 | Zn: 1 | | | | |
| | | | Mn:Co = 70:30 | Zn: 2, Ge: 2 | | | | |
| | | | Mn:Al = 49:51 | Fe: 3 | | | | |
| 13 | 100 | 102 | Mn:Zn = 98:2 | — | S | A | A | |
| 14 | 130 | 102 | Mn:Zn = 98:20 | — | A | A | A | |
| 15 | 120 | 105 | Mn:Zn = 67:33 | Si: 10 | S | A | A | |

TABLE 2

| | | A-group | B-group | | | | |
|---|---|---|---|---|---|---|---|
| | Alloy | element | element | Mn | | Molding | |
| | composition | amount | amount | amount | Raw material powder (at %) | temperapture | |
| No | (at %) | (at %) | (at %) | (at %) | ( ) indicates the mixing percentage. | (° C.) | Note |
| 16 | Co—25Zn—25Mn—25In | 50 | 25 | 25 | Mn—35Zn(31), pure Zn(10), pure In(39), pure Co(10), | 600 | Inventive examples |
| | | | | | Co—1Zn—1Mn—1In(10) | | |
| 17 | Fe—5Zn—52Mn—5Sn—5Ga—5Al—5Co | 16 | 59 | 25 | Mn—35Zn(14), Mn—24Sn(25), Mn—27Ga(22), Mn—49Co(10), | 600 | |
| | | | | | Mn—51Al(7), pure Fe(22) | | |
| 18 | Ni—25Zn—25Mn—25Sn | 25 | 50 | 25 | Mn—20Zn(10), Mn—15Sn(15), pure Sn(35), pure Zn(20), | 600 | |
| | | | | | pure Ni(20) | | |
| 19 | Ni—20Zn—25Mn—25Ga—3Ir—1Pt—1Au—1Re | 45 | 30 | 25 | Mn—20Zn(12), Mn—20Ga(12), pure Ga(22), pure Zn(16), | 700 | |
| | | | | | pure Ni(21), pure Re(3), pure Ir(8), pure Pt(3), pure Au(3) | | |
| 20 | Mn—33Zn—33Al | 66 | 0 | 34 | Mn—3Zn(30), Mn—51Al(14), pure Al(13), pure Zn(43) | 600 | |
| 21 | Mn—23Zn—10Co—33Bi | 33 | 33 | 34 | (Mn—10Zn)—3Bi(11), Mn—17Co(10), pure Zn(13), pure Co(4), | 250 | |
| | | | | | pure Bi(62) | | |
| 22 | Co—10Fe—33Mn—33Sn | 57 | 10 | 33 | Mn—1.5Sn(20), pure Mn(4), Co—20Fe—10Sn(27), pure Sn(45), | 230 | |
| | | | | | pure Co(1), pure Fe(3) | | |
| 23 | Fe—10Co—27Mn—2Gd—2Dy—2Ho—2Tb—33Sn | 43 | 30 | 27 | Mn—5Sn(18), Fe—8Gd—8Dy—8Ho—8Tb(29), pure Sn(44), | 200 | |
| | | | | | Mn—17Co(8), pure Fe(1) | | |
| 24 | Ni—25Mn—10Sn—5Ga—5Si—5Bi—5Rh—5Ru—5Ag | 15 | 60 | 25 | (Mn—15Sn)—5Ni—1Si(8), Ni(26), pure Sn(13), pure Bi(14), | 500 | |
| | | | | | Mn—27Ga(16), pure Si(2), pure Rh(7), pure Ru(7), pure Ag(7) | | |
| 25 | Cu—33Mn—20Sn—13Al | 33 | 34 | 33 | Mn—24Sn(15), Cu—80Mn(10), pure Sn(29), Mn—4Al(11), | 850 | |
| | | | | | pure Al(5), pure Cu(30) | | |
| 26 | Fe—15Co—1Zr—1Ta—31Mn—33Ga—1Sm—1Nd—1Ce—1La | 48 | 21 | 31 | Mn—2Ga(15), (Mn—8Ga)—5Zr—5Ta—5Sm—5Nd—5Ce—5La(25), | 850 | |
| | | | | | pure Ga(33), pure Fe(14), pure Co(13) | | |
| 27 | Co—25Mn—25Ga | 75 | 0 | 25 | (Mn—20Ga)—5Co(20), pure Ga(21), Mn—10Co(10), pure Co(49) | 1000 | |
| 28 | Ni—25Mn—20Ga—5Al | 25 | 50 | 25 | Mn—27Ga(20), Mn—51Al(7), pure Ga(15), pure Mn(5), | 720 | |
| | | | | | pure Ni(53) | | |

| | | | Mn phase in the sintered alloy | | | | | |
|---|---|---|---|---|---|---|---|---|
| | Flexural strength | Relative density | Ratio of | A-group element other than the left + | | | | |
| No | (MPa) | (%) | Mn and A-group element | B-group element (at %) | Size | Number | Area percentage | Note |
| 16 | 110 | 95 | Mn:Zn = 65:35 | In: 10, Co: 5 | A | A | A | Inventive examples |
| 17 | 110 | 95 | Mn:Zn = 65:35 | — | A | A | A | |
| | | | Mn:Sn = 76:24 | — | | | | |
| | | | Mn:Ga = 74:26 | Fe: 1 | | | | |
| | | | Mn:Co = 51:49 | — | | | | |
| | | | Mn:Al = 49:51 | — | | | | |
| 18 | 110 | 98 | Mn:Zn = 79:21 | — | A | A | A | |
| | | | Mn:Sn = 85:15 | — | | | | |
| 19 | 150 | 93 | Mn:Zn = 79:28 | Zn: 2, Ni: 1, Re: 1 | S | A | A | |
| | | | Mn:Ga = 85:20 | Ir: 1, Pt: 3, Au: 3 | | | | |
| 20 | 130 | 95 | Mn:Zn = 87:3 | Al: 4 | S | A | A | |
| | | | Mn:Al = 59:41 | Zn: 5 | | | | |
| 21 | 120 | 99 | Mn:Zn = 90:10 | — | S | A | A | |
| | | | Mn:Co = 82:18 | — | | | | |
| 22 | 150 | 97 | Mn:Sn = 98.5:1.5 | — | S | A | A | |
| 23 | 130 | 98 | Mn:Sn = 95:5 | — | A | A | A | |
| | | | Mn:Co = 83:17 | — | | | | |
| 24 | 120 | 97 | Mn:Sn = 85:15 | — | A | A | A | |
| | | | Mn:Ga = 73:27 | — | | | | |
| 25 | 130 | 99 | Mn:Sn = 76:24 | Cu: 3, Al: 1 | S | A | A | |
| | | | Mn:Al = 96:4 | Cu: 5 | | | | |
| 26 | 130 | 99 | Mn:Ga = 98:2 | Co: 3, Nd: 2, La: 2 | S | A | A | |
| | | | Mn:Ga = 92:8 | Zr: 5, Ta: 3, Sm: 3, Nd: 1, Ce: 3, La: 1 | | | | |
| 27 | 250 | 103 | Mn:Ga = 80:20 | Co: 10 | A | A | A | |
| | | | Mn:Co = 92:8 | Ga: 8 | | | | |
| 28 | 200 | 100 | Mn:Ga = 80:20 | Al: 1 | S | A | A | |
| | | | Mn:Al = 50:50 | Ga: 1 | | | | |

TABLE 3

| | | A-group | B-group | | | Molding | |
|---|---|---|---|---|---|---|---|
| | Alloy composition | element amount | element amount | Mn amount | Raw material powder (at %) | temperature | |
| No | (at %) | (at %) | (at %) | (at %) | ( ) indicates the mixing percentage. | (° C.) | Note |
| 29 | Mn—25Ta—25Al | 25 | 25 | 50 | Mn—51Al(25), pure Mn(18), pure Ta(57) | 680 | Inventive examples |
| 30 | Mn—25Ta—25Al | 25 | 25 | 50 | Mn—41Al(33), pure Mn(10), pure Ta(57) | 690 | |
| 31 | Mn—33Cu—33Al | 33 | 33 | 34 | Mn—4Al(10), pure Al(18), pure Mn(29), pure Cu(43) | 580 | |
| 32 | Ni—25Mn—25Al | 25 | 50 | 25 | Mn—2Al(28), pure Al(13), pure Ni(59) | 580 | |
| 33 | Ni—25Co—25Mn—25Al | 50 | 25 | 25 | Mn—30Al(20), Mn—40Co(19), pure Al(10), pure Ni(29), | 720 | |
| | | | | | pure Co(22) | | |
| 34 | Co—25Mn—25Si | 50 | 25 | 25 | Mn—4Co(28), Co—10Si(40), pure Co(20), pure Si(12) | 1000 | |
| 35 | Co—25Mn—25Si | 50 | 14 | 25 | (Mn—17Co)—9Si(35), pure Co(53), pure Si(12) | 1000 | |
| 36 | Co—25Fe—25Mn—10Ga—10Ge—1In—1Sn—3Bi | 46 | 29 | 25 | Mn—36Co(10), (Mn—8Ga)—1Fe—1Co(10), | 1000 | |
| | | | | | (Mn—8Ge)—1Fe(8), pure Co(22), pure Ga(3), pure Ge(11), | | |
| | | | | | pure In(2), pure Sn(2), pure Bi(3), pure Fe(29) | | |
| 37 | Co—10Mn—5Cr—5Mo—5W—25Si | 50 | 40 | 10 | Mn—49Co(19), pure Si(12), pure Co(41), pure Cr(4), | 1150 | |
| | | | | | pure Mo(8), pure W(16) | | |
| 38 | Co—33Mn—33Ge | 67 | 0 | 33 | Mn—0.5Ge(30), pure Ge(38), pure Co(32) | 1000 | |
| 39 | Co—10Fe—20Mn—13Cr—33Ge | 57 | 23 | 20 | Mn—25Ge(26), Co—6Ge(25), pure Ge(29), pure Cr(11), | 1000 | |
| | | | | | pure Fe(9) | | |
| 40 | Co—33Mn—33Zn | 67 | 0 | 33 | Mn—1Zn(30), pure Zn(36), pure Co(34) | 650 | |
| 41 | Co—25Zn—25Mn—25In | 50 | 25 | 25 | Mn—40Zn(30), pure Mn(1), pure Zn(9), pure In(39), | 660 | |
| | | | | | pure Co(1), Co—1Zn—1Mn—1In(20) | | |
| 42 | Co—10Fe—33Mn—33Sn | 57 | 10 | 33 | Mn—0.8Sn(20), pure Mn(4), Co—20Fe—10Sn(25), | 200 | |
| | | | | | pure Sn(46), pure Co(2), pure Fe(3) | | |
| 43 | Cu—33Mn—20Sn—13Al | 33 | 34 | 33 | Mn—28Sn(20), Cu—80Mn(8), pure Sn(26), Mn—4Al(10), | 890 | |
| | | | | | pure Al(6), pure Cu(30) | | |
| 44 | Fe—15Co—1Zr—1Ta—31Mn—33Ga | 48 | 21 | 31 | Mn—1Ga(14), (Mn—8Ga)—5Zr—5Ta(22), pure Ga(31), | 890 | |
| | | | | | pure Fe(18), pure Co(15) | | |
| 45 | Ni—25Mn—25Al | 25 | 50 | 25 | Mn—1.5Al(28), pure Al(13), pure Ni(59) | 590 | |

| | | | Mn phase in the sintered alloy | | | | | |
|---|---|---|---|---|---|---|---|---|
| | Flexural strength | Relative density | Ratio of | A-group element other than the left + | | | | |
| No | (MPa) | (%) | Mn and A-group element | B-group element (at %) | Size | Number | Area percentage | Note |
| 29 | 150 | 102 | Mn:Al = 49:51 | Ta: 6 | A | A | A | Inventive examples |
| 30 | 140 | 103 | Mn:Al = 49:41 | Ta: 5 | A | A | A | |
| 31 | 130 | 100 | Mn:Al = 96:4 | — | A | A | A | |
| 32 | 120 | 93 | Mn:Al = 98:2 | — | A | A | A | |
| 33 | 120 | 102 | Mn:Al = 70:30 | Ni: 5, Co: 1 | S | A | A | |
| | | | Mn:Co = 64:36 | Ni: 3 | | | | |
| 34 | 300 | 103 | Mn:Co = 96:4 | Si: 5 | S | A | A | |
| 35 | 300 | 105 | Mn:Co = 96:17 | Si: 13 | A | A | A | |
| 36 | 300 | 105 | Mn:Co = 64:36 | Ga: 1, In: 1, Sn: 1 | A | A | A | |
| | | | Mn:Ga = 92:8 | Bi: 3, Fe: 2 | | | | |
| | | | Mn:Ge = 92:8 | Fe: 3 | | | | |
| 37 | 400 | 103 | Mn:Co = 51:49 | Si: 4, Cr: 2, Mo: 5, W: 1 | A | A | A | |
| 38 | 140 | 97 | Mn:Ge = 98:1.5 | Co: 2 | S | A | A | |
| 39 | 110 | 99 | Mn:Ge = 79:21 | Co: 1, Cr: 2 | S | A | A | |
| | | | Mn:Co = 95:10 | Ge: 2, Fe: 1, Cr: 2 | | | | |
| 40 | 110 | 103 | Mn:Zn = 98:2 | Co: 15 | S | A | A | |
| 41 | 100 | 98 | Mn:Zn = 65:35 | In: 5, Co: 8 | S | A | A | |
| 42 | 160 | 99 | Mn:Sn = 98.5:1.5 | Fe: 5, Co: 3 | S | A | A | |
| 43 | 120 | 100 | Mn:Sn = 76:24 | Cu: 4, Al: 1 | S | A | A | |
| | | | Mn:Al = 94:6 | Cu: 1, Sn: 1 | | | | |
| 44 | 130 | 99 | Mn:Ga = 98:2 | Co: 3, Fe: 1 | S | A | A | |
| | | | Mn:Ga = 89:11 | Zr: 3, Ta: 3, Fe: 2 Co: 1 | | | | |
| 45 | 120 | 93 | Mn:Al = 98:2 | Ni: 3 | S | A | A | |

TABLE 4

| | Alloy | A-group | B-group | | | Molding | |
|---|---|---|---|---|---|---|---|
| | composition | element amount | element amount | Mn amount | Raw material powder (at %) | temperature | |
| No | (at %) | (at %) | (at %) | (at %) | ( ) indicates the mixing percentage. | (° C.) | Note |
| 46 | Mn—25Ta—25Al | 25 | 25 | 50 | Mn—53Al(24), pure Mn(19), pure Ta(57) | 700 | Inventive examples |
| 47 | Co—25Mn—25Si | 50 | 25 | 25 | Mn—2Co(28), Co—10Si(50), pure Co(11), pure Si(11) | 1100 | |
| 48 | Co—10Mn—5Cr—5Mo—5W—25Si | 50 | 40 | 10 | Mn—52Co(20), pure Si(40), pure Co(12), pure Cr(4), | 1200 | |
| | | | | | pure Mo(8), pure W(16) | | |
| 49 | Co—25Fe—25Mn—15Ge—10Al | 50 | 25 | 25 | Mn—20Ge(10), Mn—80Al(7), pure Ge(17), pure Mn(15), | 1000 | |
| | | | | | pure Fe(25), pure Co(26) | | |
| 50 | Co—30Fe—25Mn—25Ga | 45 | 30 | 25 | Mn—25Ga(20), pure Ga(20), Mn—75Co(20), pure Mn(5), | 1000 | |
| | | | | | pure Fe(30), pure Co(5) | | |
| 51 | Mn—33Zn—33Ga | 66 | 0 | 34 | Mn—27Ga(20), pure Ga(26), Mn—20Zn(20), pure Zn(32), | 1100 | |
| | | | | | pure Mn(2) | | |
| 52 | Mn—20Ni—13Cu—33Sn | 33 | 33 | 34 | Mn—28Sn(20), Mn—20Sn(20), pure Cu(11), pure Sn(34), | 280 | |
| | | | | | pure Ni(15) | | |
| 53 | Co—25Zn—25Ge—25Mn | 75 | 0 | 25 | Mn—30Co(12), Mn—38Zn(20), pure Zn(18), pure Mn(2), | 1000 | |
| | | | | | pure Ge(29), pure Co(19) | | |
| 54 | Fe—25Co—10Al—10Ge—19Mn—3Cr—3Y—5Ti | 45 | 36 | 19 | Mn—58Al(10), Mn—25Ge(10), pure Ge(10), pure Mn(6), | 1000 | |
| | | | | | pure Al(1), pure Fe(25), pure Co(26), pure Cr(3), | | |
| | | | | | pure Y(5), pure 71(4) | | |
| 55 | Ni—25Zn—25Mn—25Sn | 50 | 25 | 25 | Mn—20Zn(19), Mn—15Sn(5), pure Sn(38), pure Zn(18), | 600 | |
| | | | | | pure Ni(20) | | |

| | | | Mn phase in the sintered alloy | | | | | |
|---|---|---|---|---|---|---|---|---|
| | Flexural strength | Relative density | Ratio of | A-group element other than the left + | | | | |
| No | (MPa) | (%) | Mn and A-group element | B-group element (at %) | Size | Number | Area percentage | Note |
| 46 | 130 | 102 | Mn:Al = 49:51 | Ta: 2 | S | A | A | Inventive examples |
| 47 | 280 | 103 | Mn:Co = 96:4 | Si: 6 | S | A | A | |
| 48 | 350 | 104 | Mn:Co = 51:49 | Si: 1, W: 1, Mo: 3, Cr: 2 | S | A | A | |
| 49 | 150 | 100 | Mn:Ge = 82:18 | Fe: 5, Co: 5 | A | A | A | |
| | | | Mn:Al = 40:60 | Fe: 4, Co: 5 | | | | |
| 50 | 120 | 100 | Mn:Ga = 79:21 | Co: 3, Fe: 3 | A | A | A | |
| | | | Mn:Co = 30:70 | Fe: 2, Ga: 5 | | | | |
| 51 | 110 | 100 | Mn:Ga = 72:28 | Zn: 22 | A | A | A | |
| | | | Mn:Zn = 75:25 | Ga: 1 | | | | |
| 52 | 120 | 101 | Mn:Sn = 70:30 | Cu: 3, Ni: 1 | S | A | A | |
| | | | Mn:Zn = 76:24 | Cu: 2, Ni: 2 | | | | |
| 53 | 120 | 99 | Mn:Co = 70:30 | Ge: 8 | S | A | A | |
| | | | Mn:Zn = 62:38 | Co: 11, Ge: 5 | | | | |
| 54 | 120 | 99 | Mn:Al = 49:51 | Y: 1, Cr: 3, Co: 2, Fe: 1 | S | A | A | |
| | | | Mn:Ge = 62:23 | Y: 3, Cr: 3, Ti: 2 | | | | |
| 55 | 110 | 98 | Mn:Zn = 64:36 | — | A | A | A | |
| | | | Mn:Sn = 74:26 | Zn: 10, Ni: 10 | | | | |

Note:
Underline indicates a condition that is out of the present invention.

TABLE 5

| | | | | | | | A-group | B-group | | |
|---|---|---|---|---|---|---|---|---|---|---|
| | | Raw | | | | | element | element | Mn | |
| | Alloy | material | Molding | Flexural | Relative | | mixing | mixing | total | |
| | composition | powder | temperature | strength | density | Composition | amount | amount | amount | |
| No | (at %) | (at %) | (° C.) | (MPa) | (%) | ratio | (at %) | (at %) | (at %) | Note |
| 56 | Mn—1.5Ge | Mn—1.5Ge | 1000 | 230 | 105 | Mn:Ge = 98.5:1.5 | 1.5 | 0 | 98.5 | Inventive |
| 57 | Mn—6Ge | Mn—6Ge | 1000 | 250 | 105 | Mn:Ge = 94:6 | 6 | 0 | 94 | examples |
| 58 | Mn—12Ge | Mn—12Ge | 1000 | 260 | 105 | Mn:Ge = 88:12 | 12 | 0 | 88 | |
| 59 | Mn—21Ge | Mn—21Ge | 1000 | 230 | 106 | Mn:Ge = 79:21 | 21 | 0 | 79 | |
| 60 | Mn—2Zn | Mn—2Zn | 800 | 200 | 102 | Mn:Zn = 98:2 | 2 | 0 | 98 | |
| 61 | Mn—20Zn | Mn—20Zn | 800 | 210 | 102 | Mn:Zn = 80:20 | 20 | 0 | 80 | |
| 62 | Mn—33Zn | Mn—33Zn | 800 | 220 | 102 | Mn:Zn = 67:33 | 33 | 0 | 67 | |
| 63 | Mn—35Zn | Mn—35Zn | 800 | 200 | 102 | Mn:Zn = 65:35 | 35 | 0 | 65 | |
| 64 | Mn—1.5Sn | Mn—1.5Sn | 800 | 220 | 103 | Mn:Sn = 98.5:1.5 | 1.5 | 0 | 98.5 | |
| 65 | Mn—5Sn | Mn—5Sn | 800 | 230 | 103 | Mn:Sn = 95:5 | 5 | 0 | 95 | |
| 66 | Mn—15Sn | Mn—15Sn | 800 | 230 | 103 | Mn:Sn = 85:15 | 15 | 0 | 85 | |
| 67 | Mn—24Sn | Mn—24Sn | 800 | 230 | 103 | Mn:Sn = 76:24 | 24 | 0 | 76 | |
| 68 | Mn—2Ga | Mn—2Ga | 750 | 220 | 101 | Mn:Ga = 98:2 | 2 | 0 | 98 | |
| 69 | Mn—8Ga | Mn—8Ga | 750 | 220 | 101 | Mn:Ga = 92:8 | 8 | 0 | 92 | |
| 70 | Mn—20Ga | Mn—20Ga | 750 | 220 | 101 | Mn:Ga = 80:20 | 20 | 0 | 80 | |
| 71 | Mn—27Ga | Mn—27Ga | 750 | 230 | 101 | Mn:Ga = 73:27 | 27 | 0 | 73 | |
| 72 | Mn—4Co | Mn—4Co | 1100 | 350 | 102 | Mn:Co = 96:4 | 4 | 0 | 96 | |
| 73 | Mn—17Co | Mn—17Co | 1100 | 330 | 102 | Mn:Co = 83:17 | 17 | 0 | 83 | |
| 74 | Mn—36Co | Mn—36Co | 1100 | 330 | 102 | Mn:Co = 64:36 | 36 | 0 | 64 | |
| 75 | Mn—49Co | Mn—49Co | 1100 | 320 | 102 | Mn:Co = 51:49 | 49 | 0 | 51 | |
| 76 | Mn—2Al | Mn—2Al | 900 | 300 | 100 | Mn:Al = 98:2 | 2 | 0 | 98 | |
| 77 | Mn—4Al | Mn—4Al | 900 | 250 | 102 | Mn:Al = 96:4 | 4 | 0 | 96 | |
| 78 | Mn—41Al | Mn—41Al | 900 | 230 | 102 | Mn:Al = 59:41 | 41 | 0 | 59 | |
| 79 | Mn—51Al | Mn—51Al | 900 | 250 | 101 | Mn:Al = 49:51 | 51 | 0 | 49 | |

TABLE 6

| | | | | | Raw material | | |
|---|---|---|---|---|---|---|---|
| | | A-group | B-group | | powder (at %) | | |
| | | element | element | Mn | ( ) indicates | Molding | |
| | Alloy composition | amount | amount | amount | the mixing | temperature | |
| No | (at %) | (at %) | (at %) | (at %) | percentage. | (° C.) | Note |
| 80 | Co—33Mn—33Ge | 67 | 0 | 33 | pure Ce(32), pure Mn(29), | 900 | Comparative |
| | | | | | pure Co(39) | | examples |
| 81 | Co—25Fe—25Mn—15Ge—10Al | 50 | 25 | 25 | Mn—80Al(7), pure Ge(20), | 1000 | |
| | | | | | pure Mn(22), pure Fe(25), | | |
| 82 | Mn—1Al | 1 | 0 | 99 | Mn—1Al(—) | 900 | |
| 83 | Mn—33Zn—33Ga | 66 | 0 | 34 | Mn—27Ga(20), pure Ga(26), | 1100 | |
| | | | | | Mn—33Zn(20), pure Zn(29), | | |
| | | | | | pure Mn(5) | | |
| 84 | Mn—1Zn | 1 | 0 | 99 | Mn—1Zn(—) | 900 | |
| 85 | Mn—1Sn | 1 | 0 | 99 | Mn—1Sn(—) | 750 | |
| 86 | Mn—1Ga | 1 | 0 | 99 | Mn—1Ga(—) | 750 | |
| 87 | Mn—50Co | 50 | 0 | 50 | Mn—50Co(—) | 880 | |

| | | | Mn phase in the sintered alloy | | | | | |
|---|---|---|---|---|---|---|---|---|
| | | | | A-group | | | | |
| | | | | other | | | | |
| | | | | than the | | | | |
| | | | | left + | | | | |
| | Flexural | Relative | Ratio of | B-group | | | | |
| | strength | density | Mn and A-group | element | | | Area | |
| No | (MPa) | (%) | element | (at %) | Size | Number | percentage | Note |
| 80 | 50 | 100 | Mn:Ge = 99:1 | Co: 1 | B | B | B | Comparative |
| | | | Mn:Co = 97:3 | Ge: 1 | | | | examples |
| 81 | 50 | 100 | Mn:Al = 48:52 | Fe: 5, Co: 8, | B | B | B | |
| | | | | Ge: 3 | | | | |
| | | | Mn:Ge = 82:50 | Fe: 6, Co: 6, | | | | |
| | | | | Al: 4 | | | | |
| 82 | 50 | 100 | Mn:Al = 99:1 | — | B | B | B | |
| 83 | 50 | 100 | Mn:Ga = 76:24 | Zn: 21 | B | B | B | |
| | | | Mn:Zn = 45:55 | Ga: 18 | | | | |
| 84 | 60 | 100 | Mn:Zn = 99:1 | — | B | B | B | |
| 85 | 60 | 100 | Mn:Sn = 99:1 | — | B | B | B | |
| 86 | 50 | 100 | Mn:Ga = 99:1 | — | B | B | B | |
| 87 | 40 | 103 | Mn:Co = 50:50 | — | B | B | B | |

Note:
Underline indicates a condition that is out of the present invention.

The sintered alloy in the comparative example 80 includes a Mn—Ge phase and Mn—Co phase formed by mass transfer associated with sintering (e.g. diffusion), but these Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 81 includes a Mn—Ge phase and Mn—Al phase formed by mass transfer associated with sintering (e.g. diffusion), but these Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 82 is formed of a Mn—Al single phase, but this Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 83 includes a Mn—Ga phase and Mn—Zn phase formed by mass transfer associated with sintering (e.g. diffusion), but these Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 84 is formed of a Mn—Zn single phase, but this Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 85 is formed of a Mn—Sn single phase, but this Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 86 is formed of a Mn—Ga single phase, but this Mn phases do not correspond to any of the 1st to 6th Mn phases, therefore do not have high mechanical strength (specifically, high toughness suitable for a sputtering target material), and were not able to be used as sputtering target materials due to fragility.

The sintered alloy in the comparative example 87 is formed of a Mn—Co single phase, but this Mn phases do not correspond to any of the 1st to 6th Mn phases, therefore do not have high mechanical strength (specifically, high toughness suitable for a sputtering target material), and were not able to be used as sputtering target materials due to fragility.

In contrast, because the sintered alloys in the inventive examples 1 to 79 include one or more types of Mn phases of the 1st to 6th Mn phases in the microstructures, they have high mechanical strength (specifically, high toughness suitable for a sputtering target material). Note that, because the sintered alloys in the inventive examples 49 to 54 include a Mn phase other than the 1st to 6th Mn phases (underlined part) and also include one or more types of Mn phases of the 1st to 6th Mn phases, they have high mechanical strength (specifically, high toughness suitable for a sputtering target material). In other words, the sintered alloys in the inventive examples 1 to 79 have sufficient flexural strength and are useful as sputtering target materials that prevent occurrence of cracking during deposition by sputtering.

As described above, the present invention was completed based on the knowledge that high mechanical strengths (specifically, high toughness suitable for a sputtering target material) can be imparted to a sintered alloy by limiting the composition of a raw material powder so as to utilize γMn phase and/or βMn phase that has high toughness and introducing a Mn phase having specific composition in the sintered alloy, and thereby enabling to prevent cracking of a sputtering target material which cracking may occur during sputtering. In other words, according to the present invention, a sintered alloy having high mechanical strength (specifically, high toughness suitable for a sputtering target material) and a sputtering target material comprising the sintered alloy is provided. The sintered alloy and the sputtering target material in the present invention have sufficient flexural strength (that is, high toughness suitable for sputtering target materials) and can therefore prevent cracking of the sputtering target material which cracking may occur during deposition by sputtering.

1. A sintered alloy, comprising:
Mn;
an A-group element consisting of one or more of Ga, Zn, Sn, Ge, Al, and Co; and
optionally a B-group element consisting of one or more of Fe, Ni, Cu, Ti, V, Cr, Si, Y, Zr, Nb, Mo, Ru, Rh, Pd, Ag, In, Ta, W, Re, Ir, Pt, Au, Bi, La, Ce, Nd, Sm, Gd, Tb, Dy, and Ho,
wherein the balance is an inevitable impurity,
wherein the sintered alloy comprises one or more Mn phases selected from the group consisting of:
a 1st Mn phase comprising Mn and Ga in an atomic ratio of Mn:Ga=98:2 to 73:27, wherein the total content of the A-group element other than Ga and the B-group element is 20 at % or less;
a 2nd Mn phase comprising Mn and Zn in an atomic ratio of Mn:Zn=98:2 to 64:36, wherein the total content of the A-group element other than Zn and the B-group element is 20 at % or less;
a 3rd Mn phase comprising Mn and Sn in an atomic ratio of Mn:Sn=98.5:1.5 to 74:26, wherein the total content of the A-group element other than Sn and the B-group element is 20 at % or less;
a 4th Mn phase comprising Mn and Ge in an atomic ratio of Mn:Ge=98.5:1.5 to 79:21, wherein the total content of the A-group element other than Ge and the B-group element is 20 at % or less;
a 5th Mn phase comprising Mn and Al in an atomic ratio of Mn:Al=98:2 to 49:51, wherein the total content of the A-group element other than Al and the B-group element is 20 at % or less; and
a 6th Mn phase comprising Mn and Co in an atomic ratio of Mn:Co=96:4 to 51:49, wherein the total content of the A-group element other than Co and the B-group element is 20 at % or less.

2. The sintered alloy according to claim 1, comprising:
10 to 98.5 at % of Mn,
totally 1.5 to 75 at % of the A-group element, and
totally 0 to 62 at % of the B-group element,
wherein the balance is an inevitable impurity.

3. The sintered alloy according to claim 1, wherein the total area percentage of the 1st to 6th Mn phases is 10% or more.

4. The sintered alloy according to claim 1, wherein a density of the 1st to 6th Mn phases having sizes of 2 μm or more is one or more per 30000 μm².

5. The sintered alloy according to claim 1, wherein a density of the 1st to 6th Mn phases having sizes of 2 μm or more is one or more per 3000 μm².

6. The sintered alloy according to claim 1, wherein a relative density thereof is 90% or more.

7. The sintered alloy according to claim 1, wherein a flexural strength thereof is 100 MPa or more.

8. A sputtering target material, comprising the sintered alloy according to claim 1.
